(19) United States
(12) Patent Application Publication
(10) Pub. No.: US 2023/0065551 A1
(43) Pub. Date: Mar. 2, 2023

(54) REFLECTING MIRROR, VERTICAL CAVITY SURFACE EMITTING LASER, VERTICAL CAVITY SURFACE EMITTING LASER ARRAY, PROJECTOR, HEAD UP DISPLAY, MOVABLE BODY, HEAD MOUNT DISPLAY, OPTOMETRY APPARATUS, AND LIGHTING APPARATUS

(71) Applicants: Morimasa KAMINISHI, Miyagi (JP); Takeshi KAWASHIMA, Miyagi (JP)

(72) Inventors: Morimasa KAMINISHI, Miyagi (JP); Takeshi KAWASHIMA, Miyagi (JP)

(21) Appl. No.: 17/799,935

(22) PCT Filed: Feb. 19, 2021
(86) PCT No.: PCT/JP2021/006347

§ 371 Date: Aug. 16, 2022

(30) Foreign Application Priority Data
Feb. 25, 2020 (JP) 2020-029504
Jan. 22, 2021 (JP) 2021-008612

(51) Int. Cl. H01S 5/183; H01S 5/042; G02B 5/08

(52) U.S. Cl. CPC H01S 5/18361; H01S 5/04256; H01S 5/18347; G02B 5/0883; G02B 5/0816

(57) ABSTRACT

A reflecting mirror includes a first film and a second film on the first film, and has a reflection band where a center wavelength is λ. The first film includes a layer having a first average refractive index and another layer having a second average refractive index higher than the first average refractive index. The second film includes a layer having a third average refractive index and another layer having a fourth average refractive index higher than the third average refractive index. A sum of optical film thicknesses of the two layers of the first film is λ/2. A sum of optical film thicknesses of the two layers of the second film is greater than or equal to (n+1)λ/2 (n is an integer greater than or equal to 1).

### TECHNICAL FIELD

The present invention relates to a reflecting mirror, a vertical cavity surface emitting laser, a vertical cavity surface emitting laser array, a projector, a head up display, a movable body, a head mount display, an optometry apparatus, and a lighting apparatus.

### BACKGROUND ART

A vertical cavity surface emitting laser (VCSEL) is a laser in which a thin active layer is sandwiched between a pair of reflecting mirrors, and a resonator is formed perpendicularly to a substrate. Therefore, the reflecting mirror may be required to have reflectance greater than or equal to 99%.

A VCSEL structure in which an electrode is in contact with a spacer layer between an active layer and a reflecting mirror has been proposed (PTL1).

### SUMMARY OF INVENTION

### Technical Problem

According to a VCSEL disclosed in PTL1, although an intended purpose is achieved, a threshold gain is likely to be increased.

It is an object of the present invention to provide a reflecting mirror, a vertical cavity surface emitting laser, a vertical cavity surface emitting laser array, a projector, a head up display, a movable body, a head mount display, an optometry apparatus, and a lighting apparatus capable of reducing a threshold gain.

### Solution to Problem

According to an aspect of the present invention, a reflecting mirror includes a first multilayered film and a second multilayered film on the first multilayered film. The first multilayered film includes a first low refractive index layer having a first average refractive index and a first high refractive index layer having a second average refractive index higher than the first average refractive index. The second multilayered film includes a second low refractive index layer having a third average refractive index and a second high refractive index layer having a fourth average refractive index higher than the third average refractive index. The reflecting mirror has a reflection band where a center wavelength is λ. A sum of an optical film thickness of the first low refractive index layer and an optical film thickness of the first high refractive index layer is λ/2, and a sum of an optical film thickness of the second low refractive index layer and an optical film thickness of the second high refractive index layer is greater than or equal to (n+1)λ/2 (n is an integer greater than or equal to 1).

### Advantageous Effects of Invention

The aspect of the present invention can reduce a threshold gain.

Other objects, features and advantages of the present invention will become more apparent from the following detailed description when read in conjunction with the accompanying drawings.

### BRIEF DESCRIPTION OF DRAWINGS

FIG. 1 is a diagram depicting relationships between a thickness of a spacer layer and a device resistance.

FIG. 2 is a sectional view depicting a reflecting mirror according to a first embodiment.

FIG. 3 is a sectional view depicting a reflecting mirror according to a second embodiment.

FIG. 4 is a sectional view depicting a reflecting mirror according to a third embodiment.

FIG. 5 is a sectional view depicting a reflecting mirror according to a fourth embodiment.

FIG. 6 is a sectional view depicting a vertical cavity surface emitting laser according to a fifth embodiment.

FIG. 7 is a partially magnified view of FIG. 6.

FIG. 8 is a sectional view illustrating a vertical cavity surface emitting laser according to a sixth embodiment.

FIG. 9 is a partially magnified view of FIG. 8.

FIG. 10 is a sectional view depicting a vertical cavity surface emitting laser according to a comparative example.

FIG. 11 is a sectional view illustrating a vertical cavity surface emitting laser according to a seventh embodiment.

FIG. 12 is a sectional view illustrating a vertical cavity surface emitting laser according to an eighth embodiment.

FIG. 13 is a sectional view illustrating a vertical cavity surface emitting laser according to a ninth embodiment.

FIG. 14 is a sectional view depicting a vertical cavity surface emitting laser according to a tenth embodiment.

FIG. 15 is a sectional view illustrating a vertical cavity surface emitting laser according to an eleventh embodiment.

FIG. 16 is a sectional view depicting a vertical cavity surface emitting laser according to a twelfth embodiment.

FIG. 17 is a schematic diagram depicting a head up display as an example of a projector according to a thirteenth embodiment.

FIG. 18 is a schematic diagram depicting an automobile provided with a head up display according to the thirteenth embodiment.

FIG. 19 is a perspective view illustrating an appearance of a head mounted display according to a fourteenth embodiment.

FIG. 20 is a view partially illustrating a configuration of a head mount display according to the fourteenth embodiment.

FIG. 21 is a diagram illustrating a configuration of a lighting apparatus according to a fifteenth embodiment.

### DESCRIPTION OF EMBODIMENTS

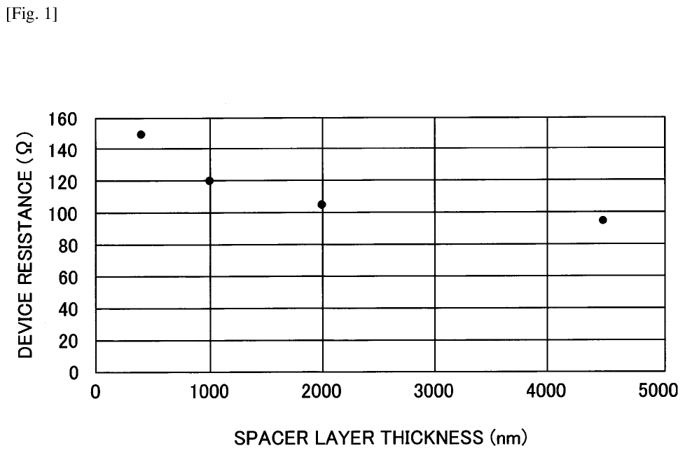

In the related art, a reduction in an optical confinement factor due to a long size of a resonator is known as one of reasons why a threshold gain of a VCSEL is likely to be increased. It is known that the thicker a spacer layer, the higher a threshold gain. However, for example, in an intracavity VCSEL, in particular, a GaN VCSEL, a spacer layer may be formed to have a great thickness to reduce a resistance (a device resistance) between two electrodes of the VCSEL. This is because in a common intracavity structure of the related art, electrodes are in contact with a spacer layer, and the thickness of the spacer layer may have a non-neglectable influence on the entire device resistance because an electric current flows through the spacer layer laterally from the active layer near the center of the device. FIG. 1 depicts a result of a simulation using a GaN VCSEL by the inventors of the present application. FIG. 1 is a diagram depicting relationships between a thickness of a spacer layer and a device resistance. FIG. 1 depicts the simulation result when a n-GaN layer was used as a spacer layer on a substrate side of an active layer. As depicted in FIG. 1, when the thickness of the spacer layer was greater than or equal to 1000 nm, the device resistance was smaller than or equal to 120Ω, while when the thickness of the spacer layer was smaller than or equal to 400 nm, the device resistance was greater than or equal to 150Ω. For this reason, in a VCSEL of the related art, a thickness of a spacer layer is greater than or equal to 1000 nm.

On the other hand, the smaller the thickness of a spacer layer, the smaller a threshold gain. A VCSEL threshold gain Gₜₕ is obtainable by Formula (1) below. In Formula (1), α_{act} denotes an absorbance loss of an active layer, α_{cld} denotes an absorbance loss of a spacer layer, α_{diff} denotes a diffraction loss, ξ denotes an optical confinement factor, L denotes a resonator length, and R denotes a reflectance of a mirror. The threshold gain Gₜₕ indicates a gain necessary for laser oscillation, and the lower this value becomes, the more likely a laser oscillates. Thus, it is desirable that a threshold gain is lower.

$$\begin{matrix}[ Math . 1 ] & \\ {G}_{th} = {α}_{a c t} + \frac{1 - ξ}{ξ} {α}_{cld} + {α}_{diff} + \frac{1}{ξ L} log ( \frac{1}{R} ) & ( 1 )\end{matrix}$$

As can be seen from Formula (1) above, if the optical confinement factor ξ can be increased, the threshold gain Gₜₕ can be reduced. Also, the optical confinement factor ξ can be increased by an increase in a percentage of an active layer in a portion of an effective resonator, the portion having a great electric field strength. That is, when the size of the active layer is predetermined, it is desirable that the thickness of the spacer layer is reduced and the length of the resonator is reduced.

However, as described above, when a thickness of a spacer layer is made smaller, a device resistance increases.

The inventors of the present application diligently studied for a structure in which a thickness of a spacer layer could be reduced while an increase in a device resistance could be avoided. As a result, it has been found out that providing a low resistance portion of a mirror is effective. By causing an electrode of a VCSEL to be in contact with the low resistance portion, a thickness of a spacer layer can be reduced while an increase in a device resistance can be avoided.

Hereinafter, embodiments of the present invention will be described with reference to the accompanying drawings. In the specification and the drawings, elements having substantially the same functions may be given the same reference numerals, and duplicate description may be omitted.

### First Embodiment

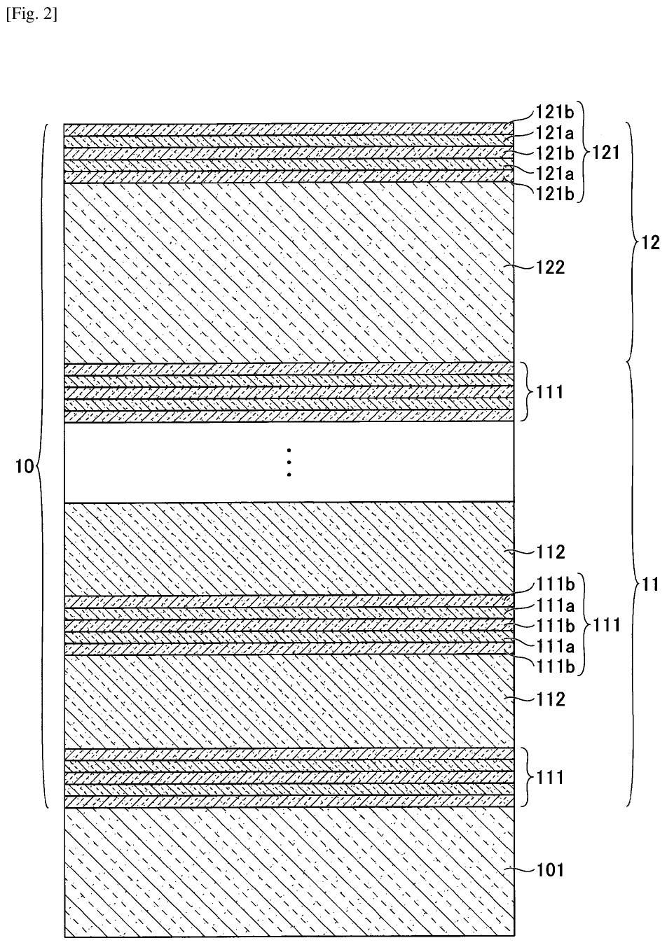

First, a first embodiment will be described. The first embodiment relates to a reflecting mirror. FIG. 2 is a sectional view depicting a reflecting mirror according to the first embodiment.

The reflecting mirror 10 according to the first embodiment has a reflection band where a center wavelength is λ. The center wavelength λ is, for example, 400 nm. As depicted in FIG. 2, the reflecting mirror 10 according to the first embodiment includes a first multilayered film 11 and a second multilayered film 12 on the first multilayered film 11.

In the first multilayered film 11, low refractive index layers 111, each having a laminate structure in which AlGaInN layers 111a and GaN layers 111b are alternately laminated, and high refractive index layers 112 each including an InGaN layer, are alternately laminated. Each of the high refractive index layers 112 may include an AlGaN layer having a low Al composition. The first multilayered film 11 includes, for example, a plurality of pairs each being a pair of a low refractive index layer 111 and a high refractive index layer 112. The first multilayered film 11 may include, in addition to pairs each being a pair of a low refractive index layer 111 and a high refractive index layer 112, one low refractive index layer 111 or one high refractive index layer 112. For example, in the first multilayered film 11, the number of low refractive index layers 111 is greater than the number of high refractive index layers 112 by 1. A composition of each of the AlGaInN layers 111a is indicated as AlₓGa_{y}In_{(1-x-y)}N, where x is greater than or equal to 0.9 and smaller than or equal to 1, and y is greater than or equal to 0 and smaller than or equal to 0.1. A refractive index of AlₓGa_{y}In_{(1-x-y)}N is lower than a refractive index of GaN. Each of the low refractive index layers 111 is an example of a first low refractive index layer, and each of the high refractive index layers 112 is an example of a first high refractive index layer. An average refractive index of a layer having a laminate structure where AlGaInN layers 111a and GaN layers 111b are alternately laminated is different from an average refractive index of a layer including an InGaN layer. An average refractive index of each of the low refractive index layers 111 is smaller than an average refractive index of each of the high refractive index layers 112. The average refractive index of each of the low refractive index layers 111 is obtained from a sum of products of optical film thicknesses and refractive indexes on a per-layer basis of the layers included in the low refractive index layer 111 being divided by the total optical film thickness of the low refractive index layer 111. The average refractive index of each of the high refractive index layers 112 is obtained from a sum of products of optical film thicknesses and refractive indexes on a per-layer basis of the layers included in the high refractive index layer 112 being divided by the total optical film thickness of the high refractive index layer 112. Each of the high refractive index layers 112 may include only an InGaN layer. In this case, the average refractive index of the high refractive index layer 112 is equal to the refractive index of the InGaN layer. The average refractive index of each of the low refractive index layers 111 is an example of a first average refractive index, and the average refractive index of each of the high refractive index layers 112 is an example of a second average refractive index.

An “optical film thickness of a layer” is obtained from a physical film thickness of the layer being multiplied with a refractive index of the layer.

The low refractive index layers 111 and the high refractive index layers 112 may be undoped semiconductor layers. The low refractive index layers 111 and the high refractive index layers 112 may be doped with impurities. “Undoped” means that doping is not performed by design and an impurity concentration in a crystal is smaller than or equal to 1×10¹⁷ cm⁻³.

The second multilayered film 12 includes one or more pairs each being a pair of a low refractive index layer 121, having a laminate structure in which AlGaInN layers 121a and GaN layers 121b are alternately laminated, and a high refractive index layer 122, which includes an InGaN layer. A composition of each of the AlGaInN layers 121a is indicated by AlₓGa_{y}In_{(1-x-y)}N, where x is greater than or equal to 0.9 and smaller than or equal to 1, and y is greater than or equal to 0 and smaller than or equal to 0.1. The composition of each of the AlGaInN layers 121a may be the same as the composition of each of the AlGaInN layers 111a, and the composition of each of the high refractive index layers 122 may be the same as the composition of each of the high refractive index layers 112. Each of the high refractive index layers 122 may be a GaN layer with an In composition of 0. Each of the low refractive index layers 121 is an example of a second low refractive index layer, and each of the high refractive index layers 122 is an example of a second high refractive index layer. An average refractive index of a layer having a laminate structure where AlGaIn layers 121a and GaN layers 121b are alternately laminated is different from an average refractive index of a layer including an InGaN layer. An average refractive index of each of the low refractive index layers 121 is smaller than an average refractive index of each of the high refractive index layers 122. The average refractive index of each of the low refractive index layers 121 is obtained from a sum of products of optical film thicknesses and refractive indexes on a per-layer basis of the layers included in the low refractive index layer 121 being divided by a total optical film thickness of the low refractive index layer 121. The average refractive index of each of the high refractive index layers 122 is obtained from products of optical film thicknesses and refractive indexes on a per-layer basis of the layers included in the high refractive index layer 122 being divided by a total optical film thickness of the high refractive index layer 122. Each of the high refractive index layers 122 may include only an InGaN layer. In this case, the average refractive index of each of the high refractive index layers 122 is equal to the refractive index of the InGaN layer. The average refractive index of each of the low refractive index layers 121 is an example of a third average refractive index, and the average refractive index of each of the high refractive index layers 122 is an example of a fourth average refractive index.

The reflecting mirror 10 is provided on a substrate 101 including, for example, GaN, and is used. For example, a material of the substrate 101 has a lattice constant of GaN, and a GaN template where a GaN substrate or a GaN layer has grown on a heterogeneous substrate can be used as the substrate 101. For example, a sapphire substrate, a Si substrate, a GaAs substrate, a SiC substrate, or the like may be used as the heterogeneous substrate.

The second multilayered film 12 has electrical conductivity. For example, the low refractive index layers 121 and the high refractive index layers 122 contain impurities such as Si at a concentration greater than or equal to 1×10¹⁸ cm⁻³, more desirably greater than or equal to 2×10¹⁸ cm⁻³.

The low refractive index layers 111 and 121 have tensile strain caused by lattice mismatch between AlGaInN of the AlGaInN layers 111a and 121a and GaN contained in the substrate 101. The high refractive index layers 112 and 122 have compression strain caused by lattice mismatch between InGaN of the high refractive index layers 112 and 122 and GaN contained in the substrate 101. Accordingly, if a difference between an amount of deformation occurring in the low refractive index layers 111 and 121 and an amount of deformation occurring in the high refractive index layers 112 and 122 is great, cracks or pits may appear at the corresponding interfaces and the reflectance may be reduced. In order to avoid appearance of such cracks and pits, it is desirable that a difference between a product P_{AlGaInN} of a distortion occurring in the AlGaInN layers 111a and 121a and a total film thickness of the AlGaInN layers 111a and 121a and a product P_{InGaN} of a distortion occurring in the InGaN layer and a total film thickness of the InGaN layer be small. For example, the product P_{AlGaInN} is desirably 0.8 to 1.2 times the product P_{InGaN}, more desirably 0.9 to 1.1 times the product P_{InGaN}, and even more desirably 1.0 times the product P_{InGaN}. A distortion ε is defined by the following formula. The denominator is the substrate's a-axis lattice constant (a_{S}), i.e., GaN's a-axis lattice constant. The numerator is a deformation amount (Δa), i.e., a result of subtracting GaN's a-axis lattice constant (a_{S}) from InGaN's or AlGaInN's a-axis lattice constant (aₑ).

ε=Δa/α_{S}=(aₑ−a_{S})/a_{S}

With respect to the first multilayered film 11, an optical film thickness of each of the low refractive index layers 111 is, for example, λ/4; and an optical film thickness of each of the high refractive index layers 112 is, for example, λ/4. A sum of the optical film thickness of each of the low refractive index layers 111 and the optical film thickness of each of the high refractive index layers 112 is, for example, λ/2. The optical film thickness of each of the low refractive index layers 111 is an example of an optical film thickness of a first low refractive index layer, and the optical film thickness of each of the high refractive index layers 112 is an example of an optical film thickness of a first high refractive index layer. As long as a sum of an optical film thickness of each of the low refractive index layers 111 and an optical film thickness of each of the high refractive index layers 112 is λ/2, the optical film thickness of each of the low refractive index layers 111 and the optical film thickness of each of the high refractive index layers 112 may be different from each other. For example, the optical film thickness of each of the high refractive index layers 112 may be greater than λ/4, and the optical film thickness of each of the low refractive index layers 111 may be smaller than λ/4. As the optical film thickness of each of the low refractive index layers 111 becomes smaller, accordingly a total film thickness of the AlGaInN layers 111a becomes greater in each of the low refractive index layers 111, a total film thickness of the GaN layers 111b in each of the low refractive index layers 111 becomes smaller, the refractive index of each of the low refractive index layers 111 becomes smaller, and effective refractive index differences between the low refractive index layers 111 and the high refractive index layers 112 become greater. Therefore, by setting the optical film thickness of each of the high refractive index layers 112 to be greater than λ/4 and the optical film thickness of each of the low refractive index layers 111 to be smaller than λ/4, the effective refractive index difference can be increased while the difference between a product P_{AlGaInN} and a product P_{InGaN} can be reduced. For example, an optical film thickness of each of the low refractive index layers 111 may be 0.8 times λ/4, and an optical film thickness of each of the high refractive index layers 112 may be 1.2 times λ/4. In this case, the sum of the optical film thickness of each of the low refractive index layers 111 and the optical film thickness of each of the high refractive index layers 112 is λ/2.

For example, each of the low refractive index layers 111 has three GaN layers 111b and two AlGaInN layers 111a. For example, each of the AlGaInN layers 111a is an AlN layer having a thickness of 5 nm, the thickness of the middle GaN layer 111b of the three GaN layers 111b is 6 nm, and the thickness of each of the GaN layers 111b at both ends is 8.5 nm. For example, the high refractive index layer 112 is an InGaN layer with a refractive index of 2.59 and a thickness of 47 nm.

With respect to the second multilayered film 12, the optical film thickness of each of the low refractive index layers 121 is, for example, λ/4, and the optical film thickness of each of the high refractive index layers 122 is, for example (2n+1)λ/4. The sum of the optical film thickness of the low refractive index layer 121 and the optical film thickness of the high refractive index layer 122 is, for example, (n+1)λ/2. The optical film thickness of each of the low refractive index layers 121 is an example of an optical film thickness of a second low refractive index layer, and the optical film thickness of each of the high refractive index layers 122 is an example of an optical film thickness of a second high refractive index layer. For example, the optical film thickness of each of the high refractive index layers 122 may be greater than (2n+1)λ/4 and the optical film thickness of each of the low refractive index layers 121 may be smaller than λ/4. As an optical film thickness of each of the low refractive index layers 121 becomes smaller, accordingly a total film thickness of AlGaInN layers 121a in each of the low refractive index layers 121 becomes greater, a total film thickness of GaN layers 121b in each of the low refractive index layers 121 becomes smaller, the refractive index of each of the low refractive index layers 121 becomes smaller, and effective refractive index differences between the low refractive index layers 121 and the high refractive index layers 122 become greater. Therefore, by setting the optical film thickness of each of the high refractive index layers 122 to be greater than (2n+1)λ/4 and the optical film thickness of each of the low refractive index layers 121 to be smaller than λ/4, the effective refractive index difference can be increased while the difference between the product P_{AlGaInN} and the product P_{InGaN} can be reduced. For example, the optical film thickness of each of the low refractive index layers 121 may be 0.8 times λ/4, and the optical film thickness of each of the high refractive index layers 122 may be 1.04 times 5λ/4. In this case, the sum of the optical film thickness of each of the low refractive index layers 121 and the optical film thickness of each of the high refractive index layers 122 is 1.5×.

For example, each of the low refractive index layers 121 has three GaN layers 121b and two AlGaInN layers 121a. For example, each of the AlGaInN layers 121a is an AlN layer with a thickness of 5 nm, the middle GaN layer 121b of the three GaN layers 121b has a thickness of 6 nm, and each of the GaN layers 121b at both sides has a thickness of 8.5 nm. For example, each of the high refractive index layers 122 is a 240 nm thick GaN layer. Each of the low refractive index layers 121 and the high refractive index layers 122 is doped, for example, with Si at a concentration of 2×10¹⁸ cm⁻³.

Concerning the reflecting mirror 10, a VCSEL resonator can be provided on the second multilayered film 12. In this case, an electrode can be provided in such a manner that a low refractive index layer 121 is etched to expose a high refractive index layer 122 and the electrode is made to contact with the high refractive index layer 122. Therefore, even in a case where a spacer layer included in the resonator and disposed on the reflecting mirror 10 side has a small thickness, an electrically conductive portion of the reflecting mirror 10, that is, the low refractive index layer 121 and the high refractive index layer 122, allows an electric current to flow through these layers, and thus, the device resistance can be kept low. Accordingly, by using the reflecting mirror 10, the threshold gain can be reduced while the device resistance can be kept low.

When the low refractive index layer 121 is etched to expose the high refractive index layer 122, an etching end timing for the low refractive index layer 121 can be determined as follows. For example, dry etching is used to etch the low refractive index layer 121, and a plasma intensity of an element not included in the high refractive index layer 122, such as Al or In, is observed using a plasma monitor. Then, it is possible to determine, as the etching end timing to end etching the low refractive index layer 121, a timing when the plasma intensity of Al, In, or the like decreases and the plasma intensity of Ga increases. Thus, an appropriate amount of the low refractive index layer 121 can be removed while excessive etching of the high refractive index layer 122 can be avoided.

The optical film thickness of the high refractive index layer 122 need not be an optical film thickness determined on the basis of 5λ/4, and may be an optical film thickness determined on the basis of 3λ/4, may be an optical film thickness determined on the basis of 7λ/4, 9λ/4, etc. In order to reduce the device resistance, it is desirable that an optical film thickness of the high refractive index layer 122 be greater than or equal to λ/2, and that the thickness of the high refractive index layer 122 be greater than or equal to 200 nm.

In the reflecting mirror 10, the sum of the optical film thickness of each of the low refractive index layers 121 and the optical film thickness of each of the high refractive index layers 122 is, for example, (n+1)λ/2 greater than λ/2, resulting in that the reflecting mirror 10 has satisfactory reflectance. Hereinafter, results of calculation of reflectance will be described. First, reflectance with respect to each of first, second, and third examples will be calculated.

In the first example, low refractive index layers and high refractive index layers are arranged alternately from the top, and then, a low refractive index layer is arranged at the bottom. The number of pairs of low refractive index layers and high refractive index layers is 45. Each of the low refractive index layers includes three GaN layers and two AlN layers. Each of the AlN layers is sandwiched between two of the GaN layers. The AlN layer is 5 nm thick, the middle GaN layer is 6 nm thick, and each of the GaN layers at both ends of is 8.5 nm thick. Each of the high refractive index layers 122 is an InGaN layer with a refractive index of 2.59 and a thickness of 47 nm. The center wavelength λ is 400 nm. The optical film thickness of each pair of low and high refractive index layers is λ/2. In a second example, the thickness of the top high refractive index layer in the first example is changed, and the optical film thickness of the pair of low refractive index layer and high refractive index layer disposed at the top is set to 2λ/2. The top high refractive index layer is a GaN layer. In a third example, the thickness of the top high refractive index layer in the first example is changed, and the optical film thickness of the pair of the low refractive index layer and the high refractive index layer disposed at the top is set to 3λ/2. The top high refractive index layer is a GaN layer. That is, each of the second example and the third example includes the pair same as the second multilayered film 12 of the first embodiment. Table 1 depicts reflectance calculation results for the first, second, and third examples.

TABLE 1

| | FIRST | SECOND | THIRD |
|---|---|---|---|
| | EXAMPLE | EXAMPLE | EXAMPLE |
| OPTICAL FILM | λ/2 | 2 λ/2 | 3 λ/2 |
| THICKNESS OF | | | |
| TOP PAIR | | | |
| REFLECTANCE | 0.995458 | 0.99529 | 0.995285 |

As depicted in Table 1, in each of both the second and third cases, the decrease in the reflectance from the first case is very small, resulting in satisfactory reflectance. If a further higher reflectance is required, the number of pairs each being similar to the second multilayered film 12 may be made greater than or equal to two.

In a VCSEL with an active layer on a reflecting mirror via a conductive spacer layer, the device resistance can be reduced in a case where the spacer layer has a great thickness. However, in this case, as described above, the resonator length is great, resulting in a lower optical confinement factor and a higher threshold gain. On the other hand, in a VCSEL having an active layer on the reflecting mirror 10 via a conductive spacer layer, reduction in the optical confinement factor can be avoided while the device resistance can be reduced.

With the use of a fourth example having a resonator length of 3× and a reflecting mirror including 50 pairs of undoped high refractive index layers and undoped low refractive index layers as a comparative example, an effect of avoiding reduction in the optical confinement factor obtained from using the reflecting mirror 10 will now be described. Table 2 below depicts optical confinement factors with respect to the fourth example, other three examples (fifth, seventh, and ninth examples) each being different from the fourth example in that the resonator lengths are 4λ, 4.5λ, and 5λ, and yet other three examples (sixth, eighth, and tenth examples) different from the fifth, seventh, and ninth examples in that the reflecting mirrors 10 are used. In the fourth example, the resonator length is 3λ and the reflecting mirror includes 50 pairs. In the fifth, seventh, and ninth examples, the resonator lengths are 4λ, 4.5λ, and 5λ, respectively, and each of the reflecting mirrors has 50 pairs. In the sixth, eighth, and tenth examples, each of the resonator lengths is 3λ, and the reflecting mirrors include 50 pairs+1λ DBR, 50 pairs+1.5λ DBR, and 50 pairs+2λ DBR, respectively. In the sixth, eighth, and tenth examples, each of the reflecting mirrors includes 50 pairs of undoped high refractive index layers and undoped low refractive index layers the same as the fourth example, and further includes one pair of conductive high refractive index layer and low refractive index layer. Each of the “+1λ DBR”, “+1.5λ DBR” and “+2λ DBR” indicates one pair of conductive high refractive index layer and low refractive index layer having an optical film thickness equivalent to the corresponding one of 1λ, 1.5λ and 2λ.

TABLE 2

| | | REFLECTING | OPTICAL |
|---|---|---|---|
| | RESONATOR | MIRROR | CONFINEMENT |
| | LENGTH | STRUCTURE | FACTOR |
| FOURTH | 3 λ | 50 PAIRS | 0.0187 |
| EXAMPLE | | | |
| FIFTH | 4 λ | 50 PAIRS | 0.0171 |
| EXAMPLE | | | |
| SIXTH | 3 λ | 50 PAIRS + | 0.0182 |
| EXAMPLE | | 1 λ DBR | |
| SEVENTH | 4.5 λ | 50 PAIRS | 0.0160 |
| EXAMPLE | | | |
| EIGHTH | 3 λ | 50 PAIRS + | 0.0165 |
| EXAMPLE | | 1.5 λ DBR | |
| NINTH | 5 λ | 50 PAIRS | 0.0158 |
| EXAMPLE | | | |
| TENTH | 3 λ | 50 PAIRS + | 0.0174 |
| EXAMPLE | | 2 λ DBR | |

As depicted in Table 2, compared to the fifth, seventh, and ninth examples where the resonator lengths are simply elongated to 4λ, 4.5λ, and 5λ from the fourth example where the resonator length is 3λ, the optical confinement factors are greater in the sixth, eighth, and tenth examples where the reflecting mirrors include the high refractive index layer and low refractive index layer having high conductivity as a multilayered film. This indicates that, in the reflecting mirror 10, it is possible to reduce the threshold gain by increasing the optical confinement factor rather than simply increasing the thickness of the spacer layer of the resonator.

### Second Embodiment

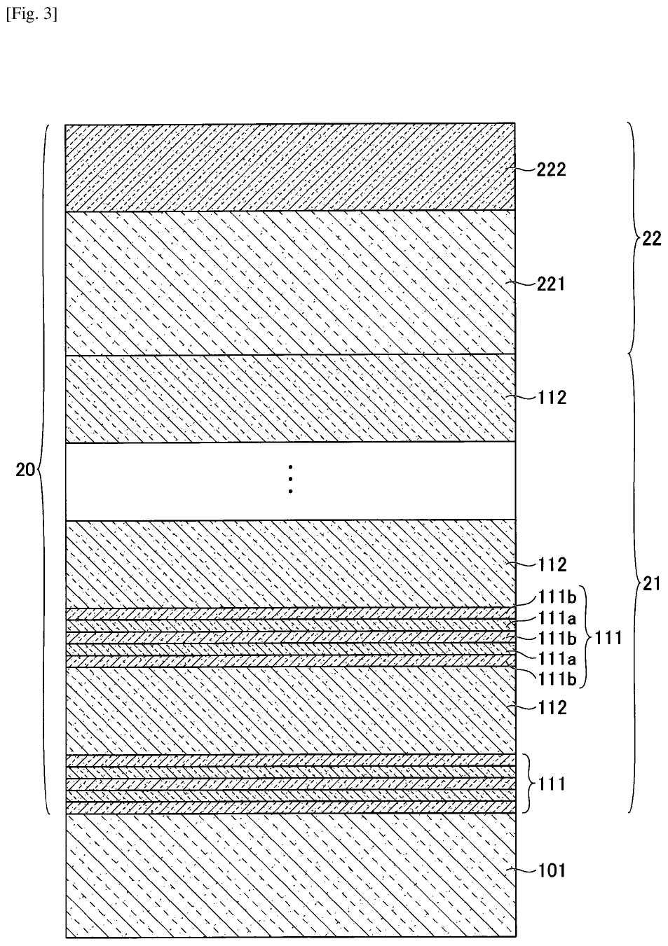

Next, a second embodiment will be described. The second embodiment relates to a reflecting mirror. FIG. 3 is a sectional view depicting the reflecting mirror according to the second embodiment.

As depicted in FIG. 3, the reflecting mirror 20 according to the second embodiment includes a first multilayered film 21 and a second multilayered film 22 on the first multilayered film 21.

In the first multilayered film 21, low refractive index layers 111 and high refractive index layers 112 are alternately laminated. In the first multilayered film 21, the number of low refractive index layers 111 is equal to the number of high refractive index layers 112.

The second multilayered film 22 includes one or more pairs each being a pair of a low refractive index layer 221 including a GaN layer and a high refractive index layer 222 including an InGaN layer. An average refractive index of a layer including a GaN layer is different from an average refractive index of a layer including an InGaN layer. An average refractive index of each of the low refractive index layers 221 is smaller than an average refractive index of each of the high refractive index layers 222. For example, each of the low refractive index layers 221 is a 217 nm thick GaN layer. For example, each of the high refractive index layers 222 is an InGaN layer with a refractive index of 2.59 and a thickness of 47 nm. For example, a sum of an optical film thickness of each of the low refractive index layers 221 and an optical film thickness of each of the high refractive index layers 222 is 2λ. A refractive index of InGaN is smaller than a refractive index of GaN. Each of the low refractive index layers 221 is an example of a second low refractive index layer, and the average refractive index of each of the low refractive index layers 221 is an example of a third average refractive index.

The second multilayered film 22 has electrical conductivity. For example, each of the low refractive index layers 221 and the high refractive index layers 222 contains impurities such as Si at a concentration greater than or equal to 1×10¹⁸ cm⁻³, desirably at a concentration greater than or equal to 2×10¹⁸ cm⁻³.

The other configurations are the same as or similar to the configurations of the first embodiment.

According to the reflecting mirror 20, a VCSEL resonator can be provided on the second multilayered film 22. In this case, an electrode can be provided in such a manner that the high refractive index layer 222 at the top is etched to expose the subsequent low refractive index layer 221 and the electrode is made contact with the low refractive index layer 221. Therefore, even in a case where the spacer layer included in the resonator and disposed on the reflecting mirror 20 side has a small thickness, the device resistance can be kept low. Accordingly, by using the reflecting mirror 20, the threshold gain can be reduced while the device resistance can be kept low.

In addition, the resistance of the second multilayered film 22 including the low refractive index layers 221, which include the GaN layers, and the high refractive index layers 222, which include the InGaN layers, can be made lower than the resistance of the second multilayered film 12 including the low refractive index layers 121, which include the AlGaInN layers 121a and the GaN layers 121b, and the high refractive index layers 122, which include the InGaN layers. Therefore, the device resistance can be further reduced.

### Third Embodiment

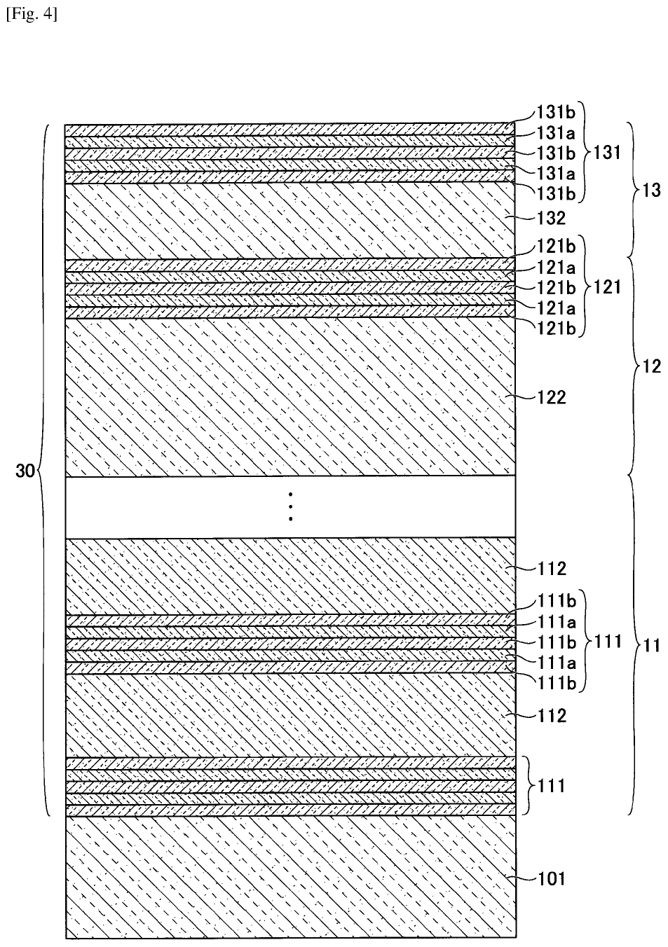

Next, a third embodiment will be described. The third embodiment relates to a reflecting mirror. FIG. 4 is a sectional view depicting the reflecting mirror according to the third embodiment.

As depicted in FIG. 4, the reflecting mirror 30 according to the third embodiment includes a first multilayered film 11, a second multilayered film 12 on the first multilayered film 11, and a third multilayered film 13 on the second multilayered film 12.

The third multilayered film 13 includes a pair of a low refractive index layer 131 having a laminate structure in which AlGaInN layers 131a and GaN layers 131b are alternately laminated and a high refractive index layer 132 including an InGaN layer. A composition of each of the AlGaInN layers 131a is indicated as AlₓGa_{y}In_{(1-x-y)}N, where x is greater than or equal to 0.9 and smaller than or equal to 1, and y is greater than or equal to 0 and smaller than or equal to 0.1. An average refractive index of a layer having a laminate structure in which AlGaInN layers 131a and GaN layers 131b are alternately laminated is different from an average refractive index of a layer including an InGaN layer. An average refractive index of the low refractive index layer 131 is smaller than an average refractive index of the high refractive index layer 132. The average refractive index of the low refractive index layer 131 is obtained as a sum of products of optical film thicknesses and refractive indexes on a per-layer basis of layers included in the low refractive index layer 131 being divided by a total optical film thickness of the low refractive index layer 131. The average refractive index of the high refractive index layer 132 is obtained as a sum of products of optical film thicknesses and refractive indexes on a per-layer basis of layers included in the high refractive index layer 132 being divided by a total optical film thickness of the high refractive index layer 132. The high refractive index layer 132 may include only an InGaN layer. In this case, the average refractive index of the high refractive index layer 132 is a refractive index of the InGaN layer itself.

The third multilayered film 13 has electrical conductivity. For example, each of the low refractive index layer 131 and the high refractive index layer 132 contains impurities such as Si at a concentration greater than or equal to 1×10¹⁸ cm⁻³, desirably greater than or equal to 2×10¹⁸ cm⁻³.

Thus, the third multilayered film 13 has the configuration same as one pair of a low refractive index layer 111 and a high refractive index layer 112 included in the first multilayered film 11, except that each of the low refractive index layer 131 and the high refractive index layer 132 has electrical conductivity.

The other configurations are the same as or similar to the configurations of the first embodiment.

According to the reflecting mirror 30, a VCSEL resonator can be provided on the third multilayered film 13. In this case, the low refractive index layer 131, the high refractive index layer 132, and the low refractive index layer 121 can be etched to expose the high refractive index layer 122, and an electrode can be provided to be in contact with the high refractive index layer 122. Therefore, even if a spacer layer included in the resonator and disposed on the reflecting mirror 30 side has a small thickness, the device resistance can be kept low. Accordingly, by using the reflecting mirror 30, the threshold gain can be reduced while the device resistance can be kept lower.

In the second embodiment, a third multilayered film in which a lamination sequence between a low refractive index layer 131 and a high refractive index layer 132 is reverse to the lamination sequence in the third multilayered film of the third embodiment may be disposed on the second multilayered film 22.

### Fourth Embodiment

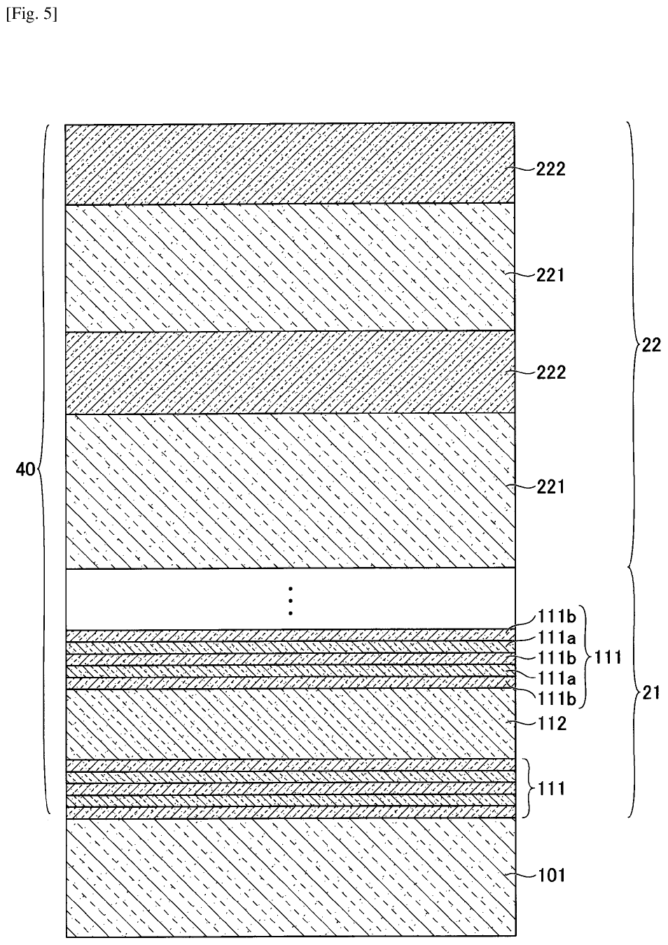

Next, a fourth embodiment will be described. A fourth embodiment relates to a reflecting mirror. FIG. 5 is a sectional view depicting the reflecting mirror according to the fourth embodiment.

As depicted in FIG. 5, in the reflecting mirror 40 according to the fourth embodiment, a second multilayered film 22 includes two pairs each being a pair of a low refractive index layer 221 and a high refractive index layer 222. For example, each of the low refractive index layers 221 is a 217 nm thick GaN layer and each of the high refractive index layers 222 is an InGaN layer with a refractive index of 2.59 and a thickness of 47 nm. In this case, a thickness of the second multilayered film 22 is greater than or equal to 500 nm.

The other configurations are the same as or similar to the configurations of the second embodiment.

According to the reflecting mirror 40, a VCSEL resonator can be provided on the second multilayered film 22. In this case, an electrode can be provided in such a manner that one high refractive index layer 222 on the resonator side is etched to expose one low refractive index layer 221 on the resonator side and the electrode is made in contact with the low refractive index layer 221. This allows the other pair of a high refractive index layer 222 and a low refractive index layer 221 to function as an electric current path for the electrode. Thus, the device resistance can be further reduced as compared to the reflecting mirror 20.

### Fifth Embodiment

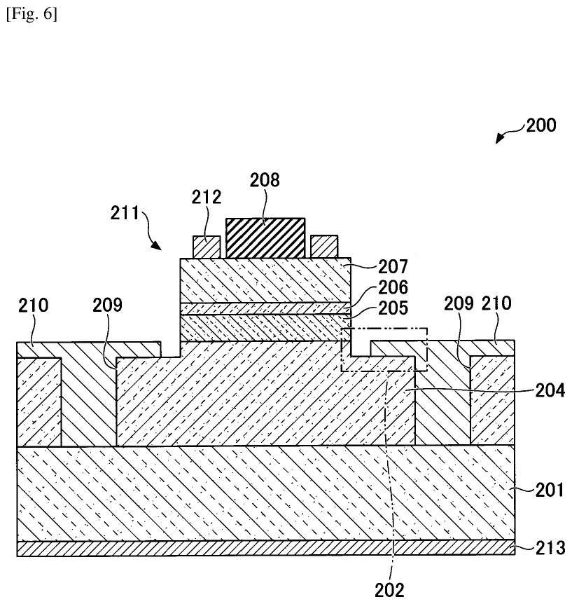

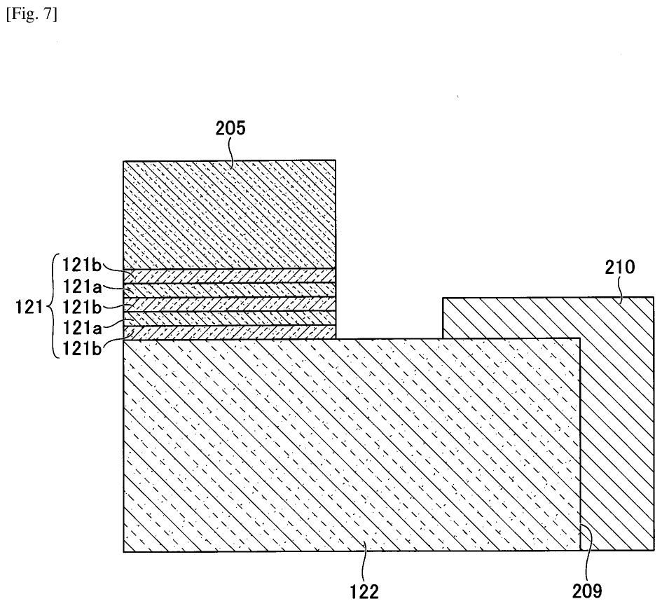

Next, a fifth embodiment will be described. The fifth embodiment relates to a vertical cavity surface emitting laser. FIG. 6 is a sectional view illustrating the vertical cavity surface emitting laser according to the fifth embodiment. FIG. 7 is a partially magnified view of FIG. 6. FIG. 7 depicts a region 202 in FIG. 6.

As depicted in FIG. 6, the vertical cavity surface emitting laser 200 according to the fifth embodiment has a substrate 201 having electrical conductivity and including GaN, a first reflecting mirror 204 on the substrate 201, and a first spacer layer having a first conductivity type (first semiconductor layer) 205 on the first reflecting mirror 204. The vertical cavity surface emitting laser 200 further includes an active layer 206 on the first spacer layer 205, a second spacer layer 207 having a second conductivity type (second semiconductor layer) on the active layer 206, and a second reflecting mirror 208 on the second spacer layer 207. The first reflecting mirror 204 includes the reflecting mirror 10 according to the first embodiment. A laminate of the first spacer layer 205, the active layer 206, and the second spacer layer 207 has a mesa structure 211. The mesa structure 211 further includes the low refractive index layer 121 of the reflecting mirror 10. An opening 209 is formed in the first reflecting mirror 204 and a conductive section 210 is provided in the opening 209. That is, the vertical cavity surface emitting laser 200 has the conductive section 210 in the opening 209 electrically connecting the substrate 201 to the high refractive index layer 122 that is located at a top surface of the first reflecting mirror 204 (the reflecting mirror 10). The vertical cavity surface emitting laser 200 further includes an upper electrode 212 on the surface of the second spacer layer 207 and a lower electrode 213 on the reverse face of the substrate 201.

The substrate 201 is, for example, a GaN substrate. The first spacer layer 205 is a first-conductivity-type semiconductor layer, such as a GaN layer, an AlGaN layer, or an InGaN layer. The first conductivity type may be either n-type or p-type, but is desirably n-type in terms of resistivity. For example, the n-type semiconductor layer may contain Si, Ge, or the like as impurities, and the p-type semiconductor layer may contain Mg, or the like.

The active layer 206 has a multi-quantum well structure made of, for example, InGaN/GaN or InGaN/InGaN. Such a multi-quantum well structure is suitable for efficiently confining carriers injected from the first spacer layer 205 or the second spacer layer 207 to achieve excellent luminous efficiency.

The second spacer layer 207 is a second-conductivity-type semiconductor layer, such as a GaN layer, an AlGaN layer, or an InGaN layer. If the first conductivity type is n, the second conductivity type is p, and if the first conductivity type is p, the second conductivity type is n. For example, the p-type semiconductor layer may contain Mg or the like, and the n-type semiconductor layer may contain Si, Ge or the like as impurities.

A resonator is formed by the first spacer layer 205, the active layer 206, and the second spacer layer 207. It is desirable that a length of the resonator, i.e., a total thickness of the first spacer layer 205, the active layer 206, and the second spacer layer 207, is greater than or equal to 1λ and smaller than or equal to 2λ, and the active layer 206 is located at a position of an antinode of an electrical field intensity distribution. This is because single mode oscillation can be easily generated.

The laminate of the low refractive index layer 121, the first spacer layer 205, the active layer 206, and the second spacer layer 207 has the mesa structure 211, for device isolation.

A material of the conductive section 210 is, for example, a conductive semiconductor or a metal. When a conductive semiconductor is used, the conductivity type of the conductive section 210 is the same as the conductivity type of the high refractive index layer 122, and the material the conductive section 210 is, for example, GaN, AlGaN or InGaN. When a metal is used, a material capable of forming an ohmic contact with the substrate 201 or the high refractive index layer 122, such a material including Ti and Al, a material including Cr and Au, or the like, is used. The substrate 201 and the conductive section 210 need not be in direct physical contact, and a buffer layer doped with impurities greater than or equal to 1×10¹⁸ cm⁻³ may be provided between the substrate 201 and the conductive section 210. Such a buffer layer helps to reduce contact resistance between the substrate 201 and the conductive section 210. The substrate 201 on which the buffer layer is formed can be regarded as a substrate including a conductive layer.

The second reflecting mirror 208 is a multilayered reflecting mirror using, for example, a semiconductor, a dielectric, or a combination of a semiconductor and a dielectric. The reflecting mirror 10 may be used as the second reflecting mirror 208. When the reflecting mirror 10 is used, heat generated at the active layer 206 can be efficiently emitted also through the second reflecting mirror 208. The second reflecting mirror 208 may have a laminate structure in which AlInN layers and GaN layers are alternately laminated. The second reflecting mirror 208 may be a multilayered reflecting mirror using another semiconductor material. Examples of the dielectric include SiN, SiO₂, Ta₂O₅, Nb₂O₅, and the like.

Reflectance of the second reflecting mirror 208 can be adjusted as follows. For example, the reflectance can be adjusted by appropriately setting the film thicknesses of the low refractive index layers and the high refractive index layers of the second reflecting mirror 208. For example, the reflectance can be adjusted by appropriately setting the film thicknesses of a Ta₂O₅ layer and a SiO₂ layer. In addition, the reflectance can be adjusted by appropriately combining laminates having different refractive index differences. For example, the reflectance can be adjusted by combining first laminates of alternating SiN and SiO₂ layers and/or second laminates of alternating Ta₂O₅ and SiO₂ layers at an appropriate cycle. The reflectance may be adjusted by adding a layer having an average refractive index different from the average refractive indexes of the low refractive index layers and the high refractive index layers.

By setting the reflectance of the second reflecting mirror 208 to be lower than the reflectance of the first reflecting mirror 204, it is possible to cause light to be emitted from the second reflecting mirror 208 side.

The upper and lower electrode 212 and 213 are made of materials capable of forming ohmic contacts with semiconductors. A material including Ni and Au is desirable for making contact with p-GaN (a p-type GaN layer), and a material including Ti and Al is desirable for making contact with n-GaN (an n-type GaN layer), but materials to be used are not limited to the above-mentioned materials.

In the vertical cavity surface emitting laser 200, the substrate 201 and the high refractive index layer 122 are electrically connected to each other via the conductive section 210. Thus, even if the first spacer layer 205 has a small thickness, it is possible to inject carriers into the active layer 206 from the substrate 201 side via the high refractive index layer 122. Accordingly, the device resistance of the vertical cavity surface emitting laser 200 is low, and the vertical cavity surface emitting laser 200 can oscillate at a low threshold gain.

In FIG. 6, the entire opening 209 is filled with the conductive section 210. However, as long as the high refractive index layer 122 and the substrate 201 are electrically connected sufficiently, it is not necessary that the entire opening 209 is filled with the conductive section 210.

### Sixth Embodiment

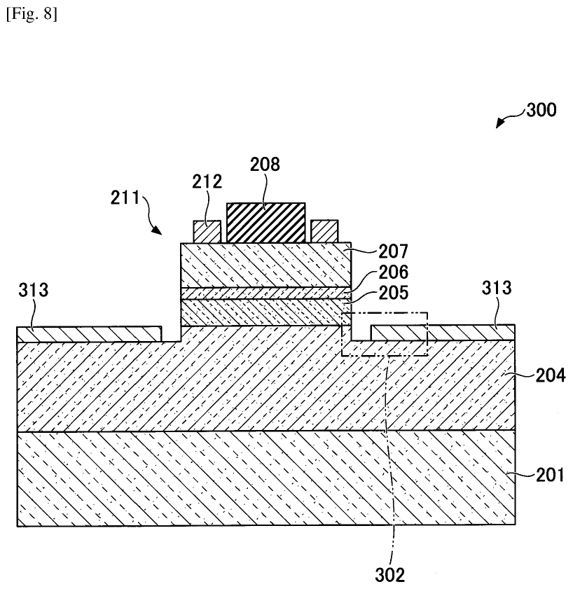

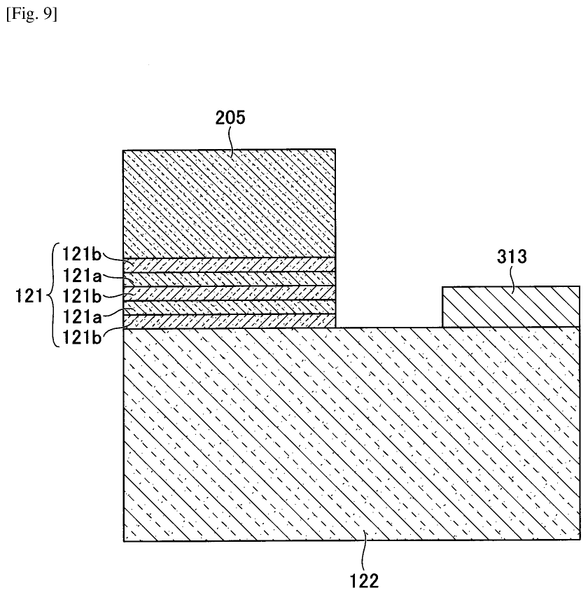

Next, a sixth embodiment will be described. The sixth embodiment relates to a vertical cavity surface emitting laser. FIG. 8 is a sectional view illustrating the vertical cavity surface emitting laser according to the sixth embodiment. FIG. 9 is a partially magnified view of FIG. 8. FIG. 9 depicts a region 302 of FIG. 8.

As depicted in FIG. 8, the vertical cavity surface emitting laser 300 according to the sixth embodiment has the same configuration as the configuration of the vertical cavity surface emitting laser 200 according to the fifth embodiment, except for several differences. For example, in the vertical cavity surface emitting laser 300, the opening 209 is not formed in the first reflecting mirror 204, and the lower electrode 213 is not provided. On the other hand, a lower electrode 313 is provided on the high refractive index layer 122 of the first reflecting mirror 204 (the reflecting mirror 10).

The lower electrode 313 is made of a material capable of forming an ohmic contact with a semiconductor. A material including Ni and Au is desirable for making contact with p-GaN, and a material including Ti and Al is desirable for making contact with n-GaN, but materials to be used are not limited to these materials.

The other configurations are the same as or similar to the configurations of the fifth embodiment.

In the vertical cavity surface emitting laser 300, the lower electrode 313 is in direct contact with the high refractive index layer 122. Thus, it is possible to inject carriers into the active layer 206 via the high refractive index layer 122 even if the first spacer layer 205 has a small thickness. Accordingly, the device resistance of the vertical cavity surface emitting laser 300 is low, and the vertical cavity surface emitting laser 300 can oscillate at a low threshold gain.

In the sixth embodiment, the substrate 201 need not have electrical conductivity.

In each of the fifth and sixth embodiments, the reflecting mirror 10 is used as the first reflecting mirror 204, but any one of the reflecting mirrors 20, 30, and 40 may be used as the first reflecting mirror 204.

### Comparative Example

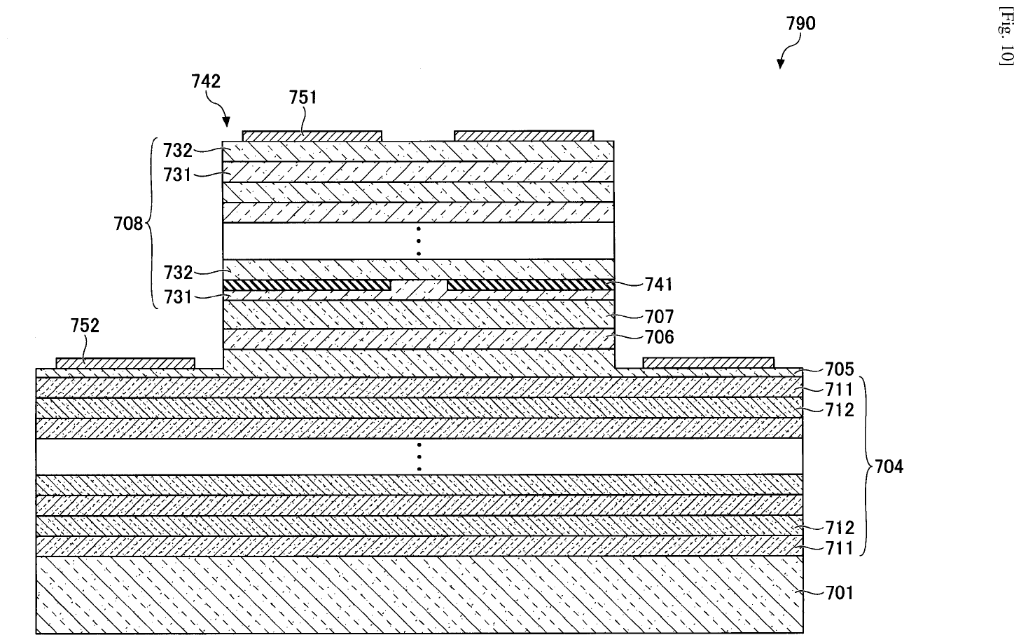

Next, a comparative example will be described. The comparative example relates to a vertical cavity surface emitting laser of a GaAs intracavity structure. FIG. 10 is a sectional view depicting the vertical cavity surface emitting laser in the comparative example.

As depicted in FIG. 10, the vertical cavity surface emitting laser 790 in the comparative example includes a substrate 701 made of GaAs, a first reflecting mirror 704 on the substrate 701, and a first-conductivity-type first spacer layer (first semiconductor layer) 705 on the first reflecting mirror 704. The vertical cavity surface emitting laser 790 further includes an active layer 706 on the first spacer layer 705, a second-conductivity-type second spacer layer 707 on the active layer 706, and a second reflecting mirror 708 on the second spacer layer 707.

Each of the first reflecting mirror 704 and the second reflecting mirror 708 has, for example, a reflection band where a center wavelength λ is 780 nm.

In the first reflecting mirror 704, low refractive index layers 711 made of AlAs and high refractive index layers 712 made of Al_{0.3}Ga_{0.7}As are alternately laminated. For example, a sum of an optical film thickness of each of the low refractive index layers 711 and an optical film thickness of each of the high refractive index layers 712 is λ/2. The optical film thickness of each of the low refractive index layers 711 is λ/4, and the optical film thickness of each of the high refractive index layers 712 is λ/4. In a case where the center wavelength λ is 780 nm, for example, the thickness of each of the low refractive index layers 711 is 65 nm and the thickness of each of the high refractive index layers 712 is 56 nm. The first reflecting mirror 704 includes, for example, a plurality of pairs, e.g., 40 pairs, of low refractive index layers 711 and high refractive index layers 712.

The first spacer layer 705 is a first-conductivity-type semiconductor layer, e.g., an n-type GaInP layer. For example, the first spacer layer 705 includes Si, Se, or the like as impurities.

The active layer 706 has a multi-quantum well structure, e.g., GaInAsP/GaInP, and emits light of 780 nm.

The second spacer layer 707 is a second-conductivity-type semiconductor layer, e.g., a p-type GaInP layer. For example, the second spacer layer 707 includes Zn or the like as an impurity.

A resonator is formed of the first spacer layer 705, the active layer 706, and the second spacer layer 707. For example, the resonator has a thickness equivalent to 2λ. For example, a portion from the lower end of the first spacer layer 705 to the center of the active layer 706 has a thickness equivalent to 1.5λ and a portion from the center of the active layer 706 to the upper end of the second spacer layer 707 has a thickness equivalent to 0.5λ.

In the second reflecting mirror 708, low refractive index layers 731, each of which is made of p-type Al_{0.9}Ga_{0.1}As, and high refractive index layers 732, each of which is made of p-type Al_{0.3}Ga_{0.7}As, are alternately laminated. For example, a sum of an optical film thickness of each of the low refractive index layers 731 and an optical film thickness of each of the high refractive index layers 732 is λ/2, the optical film thickness of each of the low refractive index layers 731 is λ/4, and the optical film thickness of each of the high refractive index layer 732 is λ/4. The second reflecting mirror 708 includes, for example, a plurality of pairs, e.g., 30 pairs, each being a pair of a low refractive index layer 731 and a high refractive index layer 732. The second reflecting mirror 708 includes an oxidized narrowing layer 741. The oxidized narrowing layer 741 includes an annular oxidized region and a non-oxidized region inside the oxidized region in plan view. An Al composition of the oxidized narrowing layer 741 is higher than Al compositions of nearby layers. For example, the oxidized narrowing layer 741 is an AlAs layer. The oxidized narrowing layer 741 functions as a current narrowing layer.

A laminate of the first spacer layer 705, the active layer 706, the second spacer layer 707, and the second reflecting mirror 708 has a mesa structure 742. A portion of the first spacer layer 705 serves as a bottom face of the mesa structure 742. The vertical cavity surface emitting laser 790 further includes an upper electrode 751 on a surface of the second reflecting mirror 708 and a lower electrode 752 on an area, i.e., an exposed area of the mesa structure 742, of a surface of the first spacer layer 705. The upper and lower electrodes 751 and 752 are made of materials capable of forming ohmic contacts with semiconductors. The upper electrode 751 is formed in an annular shape in plan view and oscillation light emits from the inside of the upper electrode 751.

For example, the first reflecting mirror 704, the first spacer layer 705, the active layer 706, the second spacer layer 707, and the second reflecting mirror 708 are formed through a metal organic chemical vapor deposition (MOCVD) process. For example, the mesa structure 742 may be formed through a photolithographic mask formation process and an inductively coupled plasma (ICP) etching process, and the like. The etching is stopped at a time point determined through an etching time management process, for example.

In the vertical cavity surface emitting laser 790, an electric current is injected from the upper electrode 751 via the p-type second reflecting mirror 708 and second spacer layer 707 into the active layer 706 while being narrowed by the oxidized narrowing layer 741. The electric current then flows from the active layer 706 via the n-type first spacer layer 705 to the lower electrode 752. In the vertical cavity surface emitting laser 790, because the first reflecting mirror 704 is undoped, light absorption by the first reflecting mirror 704 can be avoided.

However, in the vertical cavity surface emitting laser 790, the device resistance tends to be high if the first spacer layer 705 has a small thickness, whereas the threshold gain tends to be high if the first spacer layer 705 has a great thickness because the resonator length is long and the optical confinement factor is low.

### Seventh Embodiment

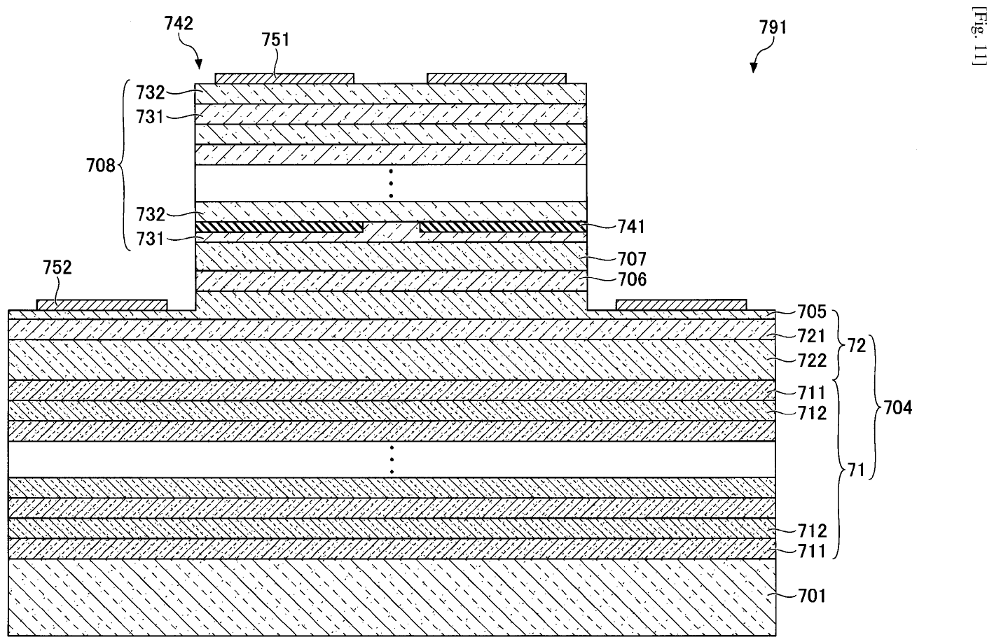

Next, a seventh embodiment will be described. The seventh embodiment relates to a vertical cavity surface emitting laser. FIG. 11 is a sectional view illustrating the vertical cavity surface emitting laser according to the seventh embodiment.

As depicted in FIG. 11, the vertical cavity surface emitting laser 791 according to the seventh embodiment has a substrate 701 made of GaAs, a first reflecting mirror 704 on the substrate 701, and a first-conductivity-type first spacer layer (first semiconductor layer) 705 on the first reflecting mirror 704. The vertical cavity surface emitting laser 790 further includes an active layer 706 on the first spacer layer 705, a second-conductivity-type second spacer layer 707 on the active layer 706, and a second reflecting mirror 708 on the second spacer layer 707.

Each of the first reflecting mirror 704 and the second reflecting mirror 708 has a reflection band where a center wavelength λ is 780 nm, for example.

The first reflecting mirror 704 has a first multilayered film 71 and a second multilayered film 72 on the first multilayered film 71.

In the first multilayered film 71, low refractive index layers 711, each of which is made of undoped AlAs, and high refractive index layers 712, each of which is made of undoped Al_{0.3}Ga_{0.7}As, are alternately laminated. For example, a sum of an optical film thickness of each of the low refractive index layers 711 and an optical film thickness of each of the high refractive index layers 712 is λ/2, the optical film thickness of each of the low refractive index layers 711 is λ/4, and the optical film thickness of each of the high refractive index layer 712 is λ/4. In a case where the center wavelength λ is 780 nm, for example, the thickness of each of the low refractive index layers 711 is 65 nm and the thickness of each of the high refractive index layers is 56 nm. The first multilayered film 71 includes, for example, a plurality of pairs, e.g., 40 pairs, of low refractive index layers 711 and high refractive index layers 712. Each of the low refractive index layers 711 is an example of a first low refractive index layer, and each of the high refractive index layers 712 is an example of a first high refractive index layer.

The second multilayered film 72 includes a single pair of a first-conductivity-type semiconductor layer, i.e., a low refractive index layer 721 made of, e.g., n-type Al_{0.9}Ga_{0.1}As, and a first-conductivity-type semiconductor layer, i.e., a high refractive index layer 722 made of, e.g., n-type Al_{0.3}Ga_{0.7}As. For example, the high refractive index layer 722 is on the first multilayered film 71 side of the low refractive index layer 721. For example, the high refractive index layer 722 is in contact with a low refractive index layer 711 and the low refractive index layer 721 is in contact with the first spacer layer 705. For example, a sum of an optical film thickness of the low refractive index layer 721 and an optical film thickness of the high refractive index layer 722 is 1λ. The low refractive index layer 721 is an example of a second low refractive index layer, and the high refractive index layer 722 is an example of a second high refractive index layer.

A resonator is formed of the first spacer layer 705, the active layer 706, and the second spacer layer 707. For example, the resonator has a thickness equivalent to 1λ. For example, a portion from the lower end of the first spacer layer 705 to the center of the active layer 706 has a thickness equivalent to 0.5λ, and a portion from the center of the active layer 706 to the upper end of the second spacer layer 707 has a thickness equivalent to 0.5λ.

The other configurations are the same as or similar to the configurations of the comparative example.

In the vertical cavity surface emitting laser 791 according to the seventh embodiment, an electric current is injected from the upper electrode 751 into the active layer 706 via the p-type second reflecting mirror 708 and second spacer layer 707, while being narrowed by the oxidized narrowing layer 741. The electric current then flows from the active layer 706 not only via the n-type first spacer layer 705 but also via the n-type low refractive index layer 721 and high refractive index layer 722 to the lower electrode 752. Therefore, the device resistance can be reduced compared to the comparative example.

Also, because the Al composition of the low refractive index layer 721 is lower than the Al composition of each of the low refractive index layers 711, the band gap of the low refractive index layer 721 is smaller than the band gap of each of the low refractive index layers 711. The difference in the band gap between the high refractive index layer 722 and the low refractive index layers 721 is smaller than the difference in the band gap between each of the high refractive index layers 712 and each of the low refractive index layers 711. Accordingly, compared to the comparative example, the hetero barrier between the first spacer layer 705 and the first reflecting mirror 704 is low and the device resistance can be reduced.

Further, because the first multilayered film 71 is undoped, even if the low refractive index layer 721 and the high refractive index layer 722 contain impurities, the light absorption by the first reflecting mirror 704 can be avoided.

Further, the resonator has a small thickness compared to the comparative example. Therefore, a great optical confinement factor is obtained and the threshold gain can be kept low.

That is, according to the seventh embodiment, both reduction in the device resistance and reduction in the threshold gain can be achieved at the same time. Reduction in the threshold gain can improve energy conversion efficiency and increase the output power. Thus, a high-power vertical cavity surface emitting laser array including a plurality of vertical cavity surface emitting lasers can be implemented.

### Eighth Embodiment

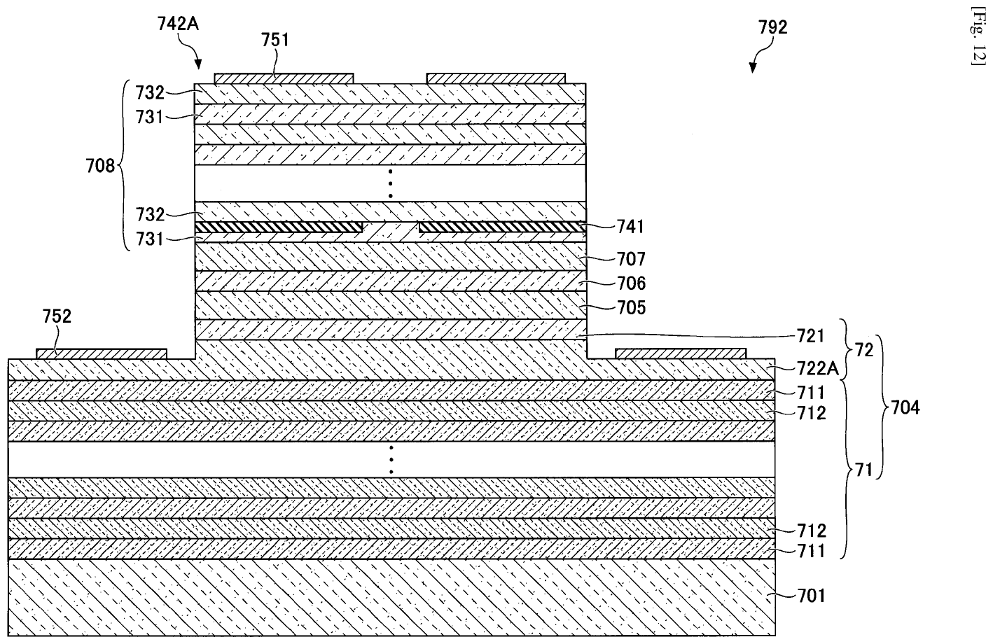

Next, an eighth embodiment will be described. The eighth embodiment relates to a vertical cavity surface emitting laser. FIG. 12 is a sectional view of the vertical cavity surface emitting laser according to the eighth embodiment.

As depicted in FIG. 12, the vertical cavity surface emitting laser 792 according to the eighth embodiment includes a substrate 701 made of GaAs, a first reflecting mirror 704 on the substrate 701, and a first-conductivity-type first spacer layer (first semiconductor layer) 705 on the first reflecting mirror 704. The vertical cavity surface emitting laser 790 further includes an active layer 706 on the first spacer layer 705, a second-conductivity-type second spacer layer 707 on the active layer 706, and a second reflecting mirror 708 on the second spacer layer 707.

A second multilayered film 72 includes a single pair of a low refractive index layer 721, i.e., a first-conductivity-type semiconductor layer made of, e.g., n-type Al_{0.9}Ga_{0.1} As, and a high refractive index layer 722A, i.e., a first-conductivity-type semiconductor layer made of, e.g., n-type GaInP. For example, a sum of an optical film thickness of the low refractive index layer 721 and an optical film thickness of the high refractive index layer 722A is 1λ, the optical film thickness of the low refractive index layer 721 is smaller than λ/4 by λ/16, and the optical film thickness of the high refractive index layer 722A is greater than 3λ/4 by λ/16.

In the eighth embodiment, a laminate of the second multilayered film 72, the first spacer layer 705, the active layer 706, the second spacer layer 707, and the second reflecting mirror 708 has a mesa structure 742A. In the mesa structure 742A, a portion of the second multilayered film 72, e.g., a portion of the high refractive index layer 722A, serves as a bottom face. A lower electrode 752 is on an area, i.e., an exposed area of the mesa structure 742A, of a surface of the high refractive index layer 722A.

The other configurations are the same as or similar to the configurations of the seventh embodiment.

In the vertical cavity surface emitting laser 792 according to the eighth embodiment, an electric current is injected from the upper electrode 751 into the active layer 706 via the p-type second reflecting mirror 708 and second spacer layer 707, while being narrowed by the oxidized narrowing layer 741. The electric current then flows from the active layer 706 via the n-type first spacer layer 705, low refractive index layer 721, and high refractive index layer 722A to the lower electrode 752. Therefore, the device resistance can be reduced compared to the comparative example.

In addition, because the optical film thickness of the high refractive index layer 722A is greater than ¾ λ, the device resistance can be further reduced.

Furthermore, the low refractive index layer 721 includes Al and the high refractive index layer 722A does not include Al. Accordingly, during forming of the mesa structure 742A, it is possible to detect the end of etching of the low refractive index layer 721 accurately by monitoring of a change in a signal with respect to Al with a plasma monitor or the like. Thus, the mesa structure 742A can be formed with better control. Further, by using a relatively-low-etching-rate material, such as GaInP, for the high refractive index layer 722A, it is possible to further improve controllability with respect to the etching process.

### Ninth Embodiment

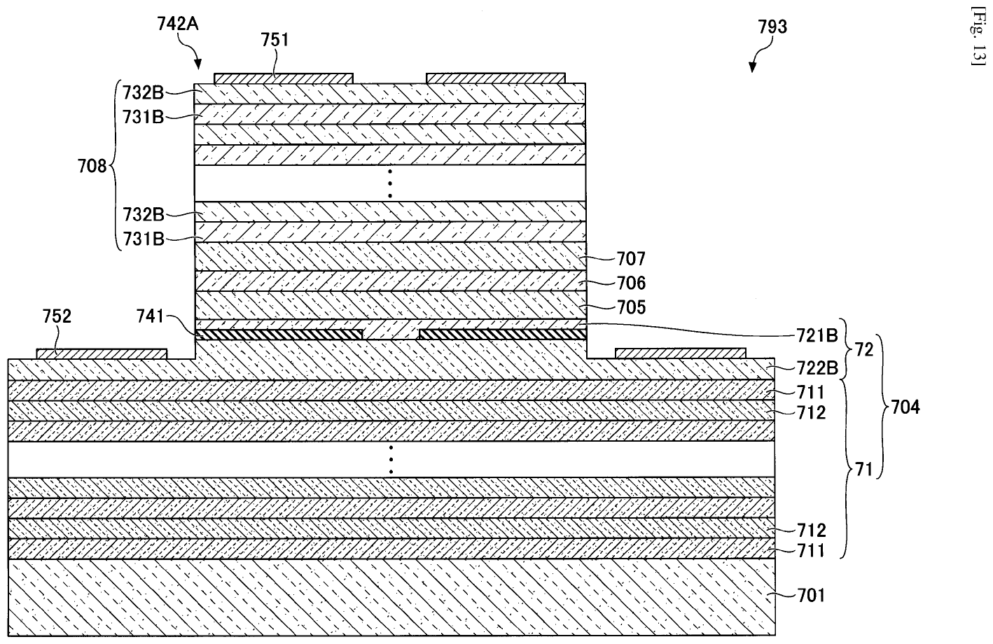

Next, a ninth embodiment will be described. The ninth embodiment relates to a vertical cavity surface emitting laser. FIG. 13 is a sectional view of the vertical cavity surface emitting laser according to the ninth embodiment.

As depicted in FIG. 13, the vertical cavity surface emitting laser 793 according to the ninth embodiment has a substrate 701 made of GaAs, a first reflecting mirror 704 on the substrate 701, and a first-conductivity-type first spacer layer (first semiconductor layer) 705 on the first reflecting mirror 704. The vertical cavity surface emitting laser 790 further includes an active layer 706 on the first spacer layer 705, a second-conductivity-type second spacer layer 707 on the active layer 706, and a second reflecting mirror 708 on the second spacer layer 707.

A second multilayered film 72 includes a single pair of a low refractive index layer 721B, i.e., a first-conductivity-type semiconductor layer made of, e.g., p-type GaInP, and a high refractive index layer 722B, i.e., a first-conductivity-type semiconductor layer made of, e.g., p-type Al_{0.8}Ga_{0.2}As. For example, a sum of an optical film thickness of the low refractive index layer 721B and an optical film thickness of the high refractive index layer 722B is 1λ, the optical film thickness of the low refractive index layer 721B is smaller than λ/4 by λ/16, and the optical film thickness of the high refractive index layer 722B is greater than 3λ/4 by λ/16.

The second multilayered film 72 includes an oxidized narrowing layer 741. The oxidized narrowing layer 741 includes an annular oxidized region and a non-oxidized region inside the oxidized region in plan view. An Al composition of the oxidized narrowing layer 741 is higher than Al compositions of nearby layers, e.g., the oxidized narrowing layer 741 is an AlAs layer. The oxidized narrowing layer 741 functions as a current narrowing layer.

In the second reflecting mirror 708, low refractive index layers 731B, made of n-type Al_{0.9}Ga_{0.1}As, and high refractive index layers 732B, made of n-type Al_{0.3}Ga_{0.7}As, are alternately laminated. For example, a sum of an optical film thickness of each of the low refractive index layers 731B and an optical film thickness of each of the high refractive index layers 732B is λ/2, the optical film thickness of each of the low refractive index layers 731B is λ/4, and the optical film thickness of each of the high refractive index layers 732B is λ/4.

A lower electrode 752 is on an area, i.e., an exposed area of the mesa structure 742A, of a surface of the high refractive index layer 722B.

The other configurations are same as or similar to the configurations of the eighth embodiment.

The ninth embodiment has the same advantageous effects as the advantageous effects of the eighth embodiment. In addition, in the ninth embodiment, compared to the eighth embodiment, the p-type region with respect to the laser light resonant direction is small. In general, a p-type semiconductor absorbs light more easily than a n-type semiconductor. Therefore, according to the ninth embodiment, light absorption in the vertical cavity surface emitting laser can be reduced compared to the eighth embodiment. Reduction of light absorption results in a higher light output and a lower threshold gain.

In general, a p-type semiconductor tends to have a higher resistance than an n-type semiconductor. However, in the ninth embodiment, the second multilayered film 72 includes the high refractive index layer 722B having a great thickness, so that an increase in the device resistance can be avoided.

### Tenth Embodiment

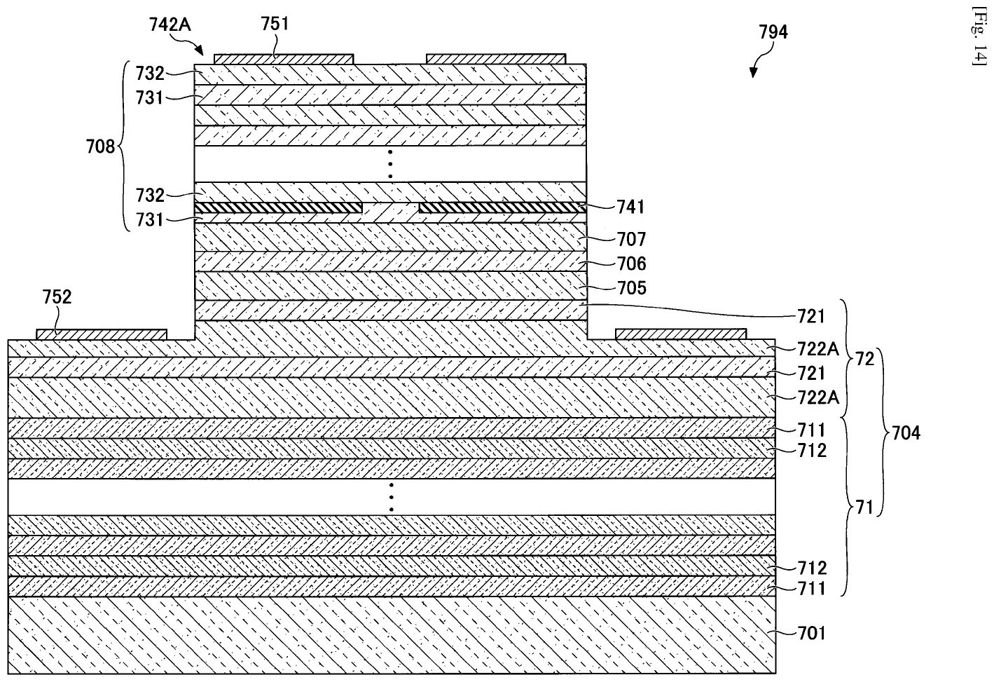

Next, a tenth embodiment will be described. The tenth embodiment relates to a vertical cavity surface emitting laser. FIG. 14 is a sectional view of the vertical cavity surface emitting laser according to the tenth embodiment.

As depicted in FIG. 14, in the vertical cavity surface emitting laser 794 according to the tenth embodiment, a second multilayered film 72 includes two pairs each being a pair of a low refractive index layer 721 and a high refractive index layer 722A. In a mesa structure 742A, a portion of the upper high refractive index layer 722A serves as a bottom face.

The other configurations are the same as or similar to the configurations of the eighth embodiment.

The tenth embodiment has the same advantageous effects as the advantageous effects of the eighth embodiment. In the tenth embodiment, because the second multilayered film 72 includes the two pairs each being a pair of a low refractive index layer 721 and a high refractive index layer 722A, the device resistance can be made lower. Further, according to the tenth embodiment, a reflectance of the first reflecting mirror 704 can be increased. For example, the reflectance of the first reflecting mirror 704 in the tenth embodiment can be made higher than the reflectance of the first reflecting mirror 704 in the eighth embodiment where the high refractive index layer 722A is made to have a greater thickness to reduce the device resistance.

### Eleventh Embodiment

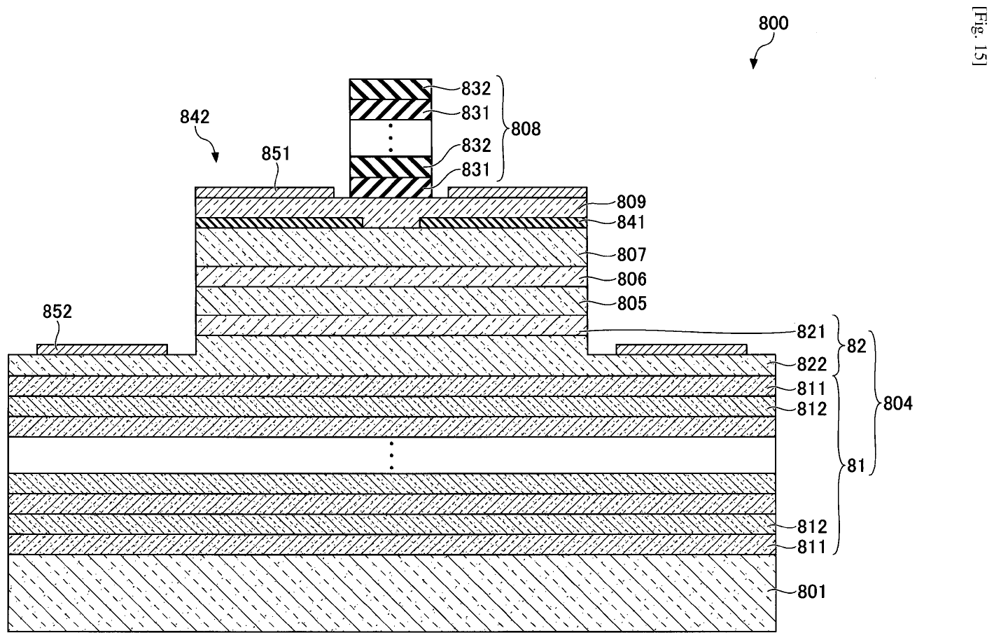

Next, an eleventh embodiment will be described. The eleventh embodiment relates to a vertical cavity surface emitting laser. FIG. 15 is a sectional view illustrating the vertical cavity surface emitting laser according to the eleventh embodiment.

As depicted in FIG. 15, the vertical cavity surface emitting laser 800 according to the eleventh embodiment includes a substrate 801 made of GaN, a first reflecting mirror 804 on the substrate 801, and a first-conductivity-type first spacer layer (first semiconductor layer) 805 on the first reflecting mirror 804. The vertical cavity surface emitting laser 800 further includes an active layer 806 on the first spacer layer 805, a second-conductivity-type second spacer layer 807 on the active layer 806, and a transparent conductive film 809 on the second spacer layer 807.

The first reflecting mirror 804 has a reflection band where a center wavelength λ is, e.g., 410 nm.

The first reflecting mirror 804 has a first multilayered film 81 and a second multilayered film 82 on the first multilayered film 81.

In the first multilayered film 81, low refractive index layers 811, made of undoped AlInN, and high refractive index layers 812, made of undoped GaN, are alternately laminated. The low refractive index layers 811 are lattice-matched to the high refractive index layers 812. For example, a sum of an optical film thickness of each of the low refractive index layers 811 and an optical film thickness of each of the high refractive index layers 812 is λ/2, the optical film thickness of each of the low refractive index layers 811 is λ/4, and the optical film thickness of each of the high refractive index layers 812 is λ/4. In a case where the center wavelength λ is 410 nm, for example, the thickness of each of the low refractive index layers 811 is 46 nm and the thickness of each of the high refractive index layers is 41 nm. The first multilayered film 81 includes, for example, a plurality of pairs, e.g., 45 pairs, each being a pair of a low refractive index layer 811 and a high refractive index layer 812. Each of the low refractive index layers 811 is an example of a first low refractive index layer, and each of the high refractive index layers 812 is an example of a first high refractive index layer.

The second multilayered film 82 includes a single pair of a first-conductivity-type semiconductor layer, which is a low refractive index layer 821 made of, for example, n-type Al_{0.2}Ga_{0.8}N, and a first-conductivity-type semiconductor layer, which is a high refractive index layer 822 made of, for example, n-type GaN. For example, the high refractive index layer 822 is on the first multilayered film 81 side of the low refractive index layer 821. For example, the high refractive index layer 822 is in contact with a low refractive index layer 811 and the low refractive index layer 821 is in contact with the first spacer layer 805. For example, a sum of an optical film thickness of the low refractive index layer 821 and an optical film thickness of the high refractive index layer 822 is 1.5λ, the optical film thickness of the low refractive index layer 821 is smaller than λ/4 by λ/16, and the optical film thickness of the high refractive index layer 822 is greater than 5λ/4 by λ/16. The low refractive index layer 821 is an example of a second low refractive index layer, and the high refractive index layer 822 is an example of a second high refractive index layer.

The first spacer layer 805 is a first-conductivity-type semiconductor layer, e.g., an n-type GaN layer. The active layer 806 has a multi-quantum well structure, e.g., InGaN/GaN, and emits light of 410 nm. The second spacer layer 807 is a second-conductivity-type semiconductor layer, e.g., a p-type GaN layer.

A resonator is formed of the first spacer layer 805, the active layer 806, and the second spacer layer 807. For example, the resonator has a thickness equivalent to 2λ. For example, a portion from the lower end of the first spacer layer 805 to the center of the active layer 806 has a thickness equivalent to 0.5λ, and a portion from the center of the active layer 806 to the upper end of the second spacer layer 807 has a thickness equivalent to 1.5λ.

A laminate of the second multilayered film 82, the first spacer layer 805, the active layer 806, and the second spacer layer 807 has a mesa structure 842. In the mesa structure 842, a portion of the second multilayered film 82, e.g., a portion of the high refractive index layer 822 serves as a bottom face.

The vertical cavity surface emitting laser 800 has an annular insulating layer 841 in plan view on the mesa structure 842. The insulating layer 841 is, for example, a SiO₂ layer. A transparent conductive film 809 is on the insulating layer 841 and in contact with the second spacer layer 807 via an opening formed through the insulating layer 841. The transparent conductive film 809 is, for example, an indium tin oxide (ITO) film.

The vertical cavity surface emitting laser 800 has an upper electrode 851 on a top face of the transparent conductive film 809 and a lower electrode 852 on an area, i.e., an exposed area of the mesa structure 842, of a surface of the high refractive index layer 822. The upper electrode 851 and the lower electrode 852 are made of materials each capable of forming an ohmic contact with a semiconductor. The upper electrode 851 is annularly formed in plan view.

The vertical cavity surface emitting laser 800 has a second reflecting mirror 808 on the transparent conductive film 809 inside the upper electrode 851. The second reflecting mirror 808 has a reflection band where a center wavelength λ is, e.g., 410 nm. The second reflecting mirror 808 is, for example, a distributed Bragg reflector (DBR). In the second reflecting mirror 808, low refractive index layers 831 made of SiO₂ and high refractive index layers 832 made of Ta₂O₅ are alternately laminated. The second reflecting mirror 808 includes, for example, a plurality of pairs, e.g., 10 pairs, each being a pair of a low refractive index layer 831 and a high refractive index layer 832.

For example, the first reflecting mirror 804, the first spacer layer 805, the active layer 806, and the second spacer layer 807 are formed by a MOCVD method. For example, the mesa structure 842 may be formed by a photolithographic mask formation process and a ICP etching process. For example, the insulating layer 841 may be formed by a photolithographic mask formation process and an etching process.

In the vertical cavity surface emitting laser 800, an electric current is injected from the upper electrode 851 into the active layer 806 via the second spacer layer 807 while being narrowed by the insulating layer 841. The electric current then flows from the active layer 806 to the lower electrode 852 via the n-type first spacer layer 805, low refractive index layer 821, and high refractive index layer 822. Therefore, the device resistance can be reduced.

In the eleventh embodiment, an Al composition of the low refractive index layer 821 is lower than an Al composition of each of the low refractive index layers 811, and the band gap of the low refractive index layer 821 is smaller than the band gap of each of the low refractive index layers 811. The difference in the band gap between the high refractive index layer 822 and the low refractive index layer 821 is smaller than the difference in the band gap between each of the high refractive index layers 812 and each of the low refractive index layers 811. Accordingly, the hetero barrier between the first spacer layer 805 and the first reflecting mirror 804 is low and the device resistance can be reduced.

### Twelfth Embodiment

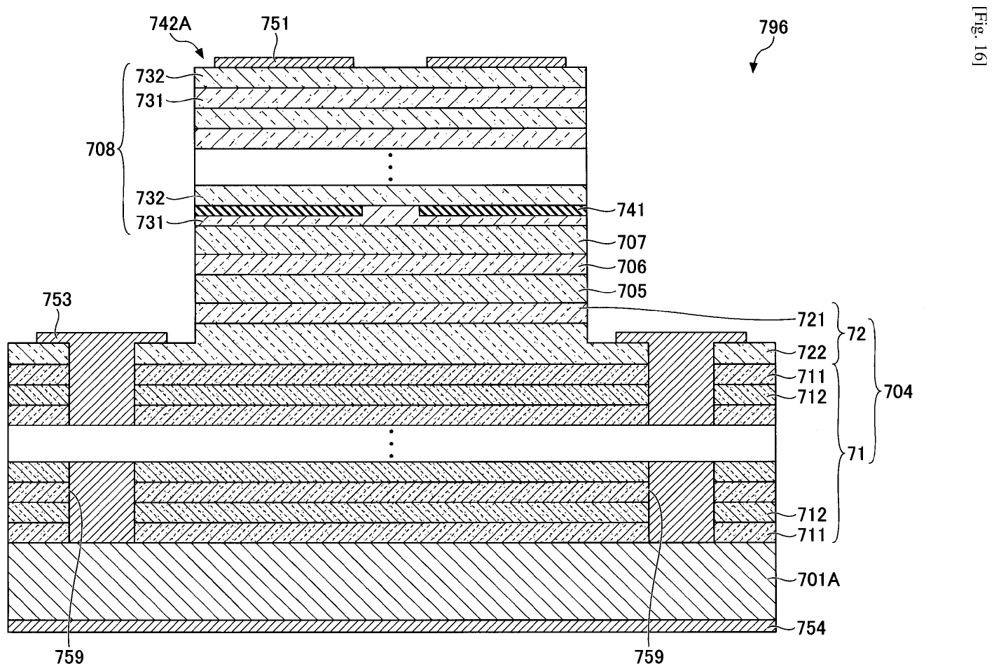

Next, a twelfth embodiment will be described. The twelfth embodiment relates to a vertical cavity surface emitting laser. FIG. 16 is a sectional view of the vertical cavity surface emitting laser according to the twelfth embodiment.

As depicted in FIG. 16, the vertical cavity surface emitting laser 796 according to the twelfth embodiment includes a conductive substrate 701A instead of a substrate 701. An opening 759 is formed through a first reflecting mirror 704 and a conductive section 753 is provided in the opening 759. That is, the vertical cavity surface emitting laser 796 has the conductive section 753 in the opening 759 electrically connecting the substrate 701A with a high refractive index layer 722 located at a top surface of the first reflecting mirror 704. The vertical cavity surface emitting laser 796 further has a lower electrode 754 on a reverse face of the substrate 701A. Because the high refractive index layer 722 is electrically connected with the substrate 701A via the conductive section 753, it is possible to use the first multilayered film that is undoped.

In the vertical cavity surface emitting laser 796, the substrate 701A and the high refractive index layer 722 are electrically connected to each other via the conductive section 753. Thus, even in a case where the first spacer layer 705 has a small thickness, it is possible to inject carriers into the active layer 706 from the substrate 701A side via the high refractive index layer 722. Accordingly, the device resistance of the vertical cavity surface emitting laser 796 is low, and the vertical cavity surface emitting laser 796 can oscillate at a low threshold gain. In addition, because it is possible to use the first multilayered film that is undoped, it is possible to reduce light absorption, resulting in that the vertical cavity surface emitting laser 796 can oscillate at a further low threshold gain.

### Thirteenth Embodiment

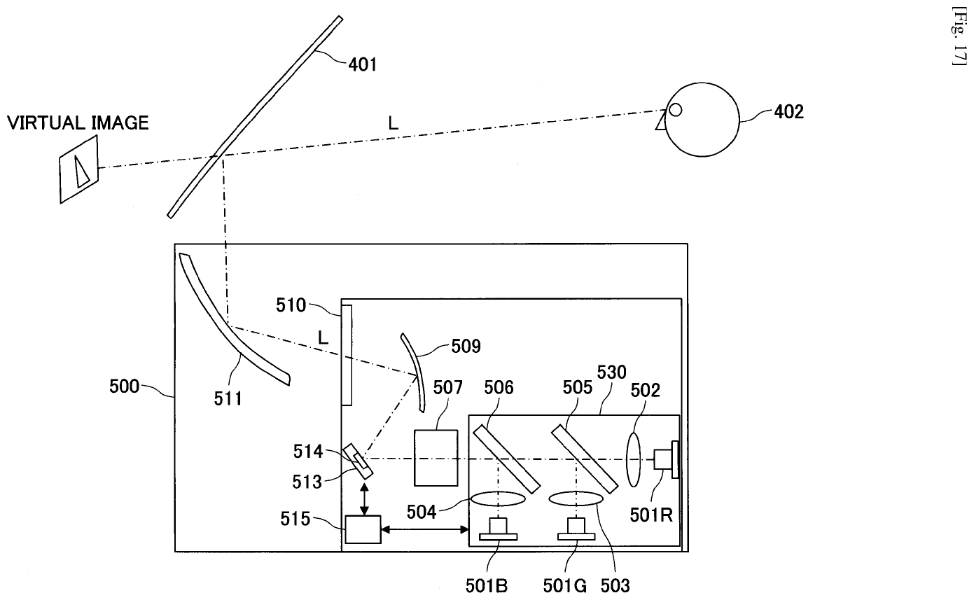

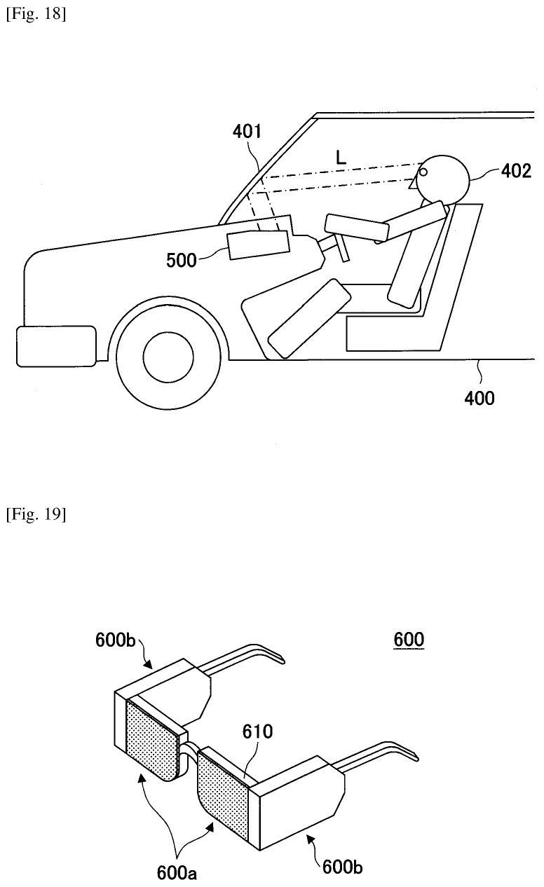

Next, a thirteenth embodiment will be described. The thirteenth embodiment relates to a head up display (HUD), which is an example of a projector. FIG. 17 is a schematic diagram illustrating a HUD that is an example of a projector according to the thirteenth embodiment. FIG. 18 is a schematic view illustrating an automobile mounted with the HUD according to the thirteenth embodiment.

A projector is an apparatus for projecting an image through optical scanning (light deflection), for example, an HUD.

The HUD 500 according to the thirteenth embodiment is installed, for example, near a windshield (such as a windshield 401) of the automobile 400, as depicted in FIG. 18. Projection light L emitted from the HUD 500 is reflected by the windshield 401 toward an observer who is a user (driver 402). This allows the driver 402 to see an image or the like projected by the HUD 500 as a virtual image. A combiner may be provided on an inner wall of the windshield to allow the user to see a virtual image through projection light reflected by the combiner. The automobile 400 is an example of a movable body.

As depicted in FIG. 17, the HUD 500 emits laser light from red, green, and blue laser light sources 501R, 501G, and 501B. The emitted laser light is deflected by a movable device 513 having a reflective surface 514 after passing through an incident optical system including collimator lenses 502, 503, and 504 provided for the laser light sources 501R, 501G, and 501B, two dichroic mirrors 505 and 506, and a light intensity adjusting unit 507. The deflected laser light is then projected onto a screen via a projection optical system including a free-form mirror 509, an intermediate screen 510, and a projection mirror 511. In the above-described HUD 500, the laser light sources 501R, 501G, and 501B, the collimator lenses 502, 503, and 504, and the dichroic mirrors 505 and 506 are included in an optical housing to be one unit as a light source unit 530. The laser light sources 501R, 501G, and 501B include vertical cavity surface emitting lasers according to any of the fifth through twelfth embodiments. The laser light sources 501R, 501G, and 501B may include vertical cavity surface emitting laser arrays each including a plurality of vertical cavity surface emitting lasers according to any of the fifth through twelfth embodiments.

The HUD 500 projects an intermediate image displayed on the intermediate screen 510 to the windshield 401 of the automobile 400, causing the intermediate image to be seen as a virtual image by the driver 402.

Laser light beams of the respective colors emitted from the laser light sources 501R, 501G, and 501B are made to be substantially parallel at the collimator lenses 502, 503, and 504, and are combined by the two dichroic mirrors 505 and 506 that serve as a combining unit. The combined laser light is deflected in two dimensions by the movable device 513 having the reflective surface 514 after the light intensity is adjusted by the light intensity adjusting unit 507. The projection light L, which has been two-dimensionally deflected by the movable device 513, is reflected by the free-form mirror 509 to correct distortion and condense the projection light L onto the intermediate screen 510 to display the intermediate image. The intermediate screen 510 includes a microlens array having a two-dimensional arrangement of micro-lenses to magnify the projection light L incident on the intermediate screen 510 on a permicrolens basis.

The movable device 513 rotates in a go and return manner the reflective surface 514 in two axial directions and deflects two-dimensionally the projection light L incident on the reflective surface 514. Driving control of the movable device 513 is in synchronization with light emission timing of the laser light sources 501R, 501G, and 501B.

The light source unit 530 and the movable device 513 are controlled by a controller 515.

Thus, the HUD 500 has been described as an example of a projector. However, as long as a projector is an apparatus for projecting an image through light deflection implemented by a movable device 513 having a reflective surface 514, any other type of a projector may be an embodiment of the present invention. For example, examples of a projector according to an embodiment of the present invention includes: a projector placed on a desk or the like to project an image onto a display screen; a head mount display provided to a mounting member that is mounted on a viewer's head or the like to project an image on a reflection and transmission screen also provided to the mounting member, or to project an image on an eye of the viewer used as a screen; and the like.

A projector may be provided not only in a vehicle or to a mounting member, but also, for example, in a movable body such as an aircraft, a ship, or a moving robot, or a non-movable body such as a working robot that operates a driving target such as a manipulator while the working robot itself does not move.

### Fourteenth Embodiment

Next, a fourteenth embodiment will be described. The fourteenth embodiment relates to a head mount display (HMD). FIG. 19 is a perspective view of one example of the HMD according to the fourteenth embodiment.

The HMD is a head mount display attachable to a human head, for example, and may have a shape similar to spectacles.

The HMD 600 according to the fourteenth embodiment includes two pairs each including a front 600a and a temple 600b provided substantially symmetrically at left and right sides as depicted in FIG. 19. Each of the fronts 600a may include, for example, a light guide plate 610. Optical systems, control devices, and the like may be inside the temples 600b.

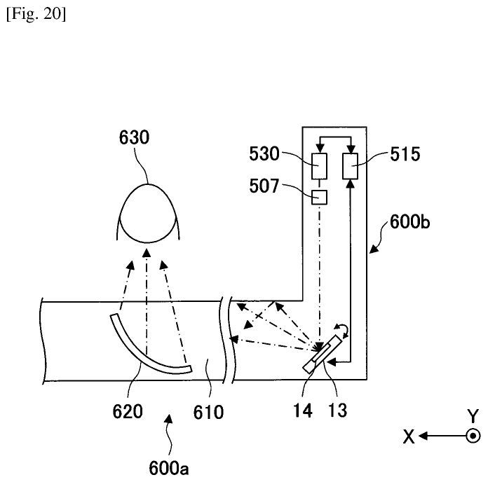

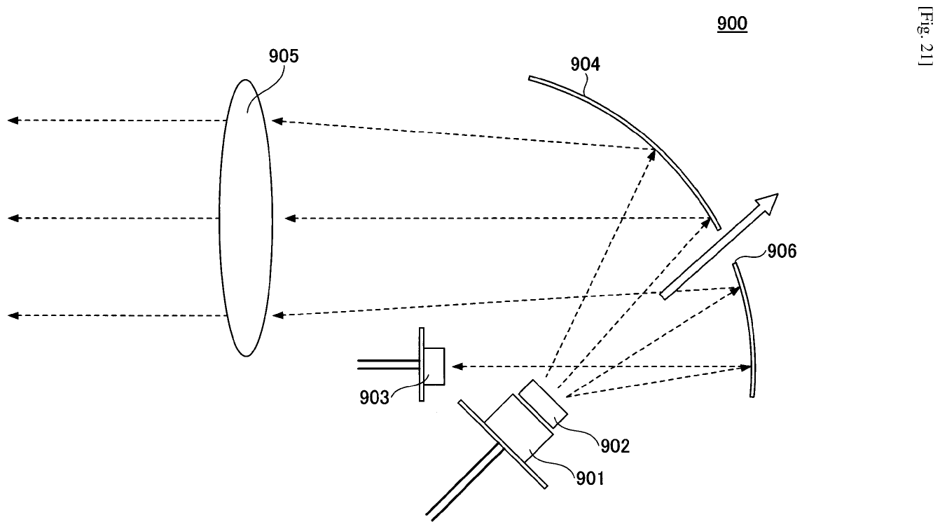

FIG. 20 is a diagram illustrating in part a configuration of the HMD 600. Although FIG. 20 illustrates a configuration for a left eye, the HMD 600 has the same configuration also for a right eye.

The HMD 600 includes a controller 515, a light source unit 530, a light intensity adjusting unit 507, a movable device 513 having a reflective surface 514, a light guide plate 610, and a half mirror 620.

The light source unit 530 is such that, in an optical housing, laser light sources 501R, 501G, and 501B, collimator lenses 502, 503, and 504, and dichroic mirrors 505 and 506 are included to be one unit, as described above. In the light source unit 530, three laser light beams of the respective colors from the laser light sources 501R, 501G, and 501B are combined by the dichroic mirrors 505 and 506 that are a combining unit. The combined parallel light is then emitted from the light source unit 530. The laser light sources 501R, 501G, and 501B include vertical cavity surface emitting lasers according to any of the fifth through twelfth embodiments. The laser light sources 501R, 501G, 501B may include vertical cavity surface emitting laser arrays each including a plurality of vertical cavity surface emitting lasers according to any of the fifth through twelfth embodiments.

The light from the light source unit 530 is incident on the movable device 513 after the light intensity is adjusted by the light intensity adjusting unit 507. The movable device 513 moves the reflective surface 514 in XY directions based on a signal from the controller 515 and deflects the light from the light source unit 530 in two dimensions. Driving control of the movable device 513 is performed in synchronization with light emission timing of the laser light sources 501R, 501G, and 501B, and a color image is formed through scanning with the deflected light.

The deflected light from the movable device 513 is incident on the light guide plate 610. The light guide plate 610 guides the deflected light toward the half mirror 620 while reflecting the light with its inner wall. The light guide plate 610 is made of a resin or the like that has a transmission property with respect to the wavelength of the deflected light.

The half mirror 620 reflects the light from the light guide plate 610 toward a rear side of the HMD 600 and guides the light in the direction of an eye of a person (wearer 630) who has the HMD 600 mounted on the head of the person. The half mirror 620 has, for example, a free-form shape. An image formed through scanning by the deflected light is focused onto a retina of the wearer 630 after being reflected by the half mirror 620. Alternatively, through reflection by the half mirror 620 and a lens effect of a crystalline lens of the eye, an image is formed on the retina of the wearer 630. Reflection by the half mirror 620 corrects spatial distortion of the image. Thus, the wearer 630 can observe the image formed through scanning by light deflected in the XY directions.

Because the half mirror 620 is provided at the front 600a, the wearer 630 can view an image formed with light coming from the outside superimposed with an image formed through the scanning with deflected light. Instead of the half mirror 620, a mirror may be provided to allow only the deflected image to be viewed while avoiding the light coming from the outside.

### Fifteenth Embodiment

Next, a fifteenth embodiment will be described. The fifteenth embodiment relates to an optometry apparatus.

The optometry apparatus according to the fifteenth embodiment is an apparatus capable of performing various tests such as a visual acuity test, an eye refractive power test, an intraocular pressure test, and an eye axial length test. The optometry apparatus is a non-contact eye testing apparatus that includes a support for a subject's face, an optometric window, a display unit for projecting information for testing onto the subject's eye upon optometry, a control unit, and a measurement unit. The subject's face is placed on the support and the subject stares at information for testing projected through the optometry window by the display unit. A vertical cavity surface emitting laser according to any one of the fifth through twelfth embodiments can be used as a light source for projecting the information for testing. A vertical cavity surface emitting laser array including a plurality of vertical cavity surface emitting lasers according to any one of the fifth through twelfth embodiments may be used as a light source for projecting the information for testing. The optometry apparatus may have a shape like spectacles. The optometry apparatus having a shape like spectacles eliminates the need for an examination space and for a large-sized optometry apparatus, enabling implementing tests with a simple configuration without being dependent on location.

### Sixteenth Embodiment

Next, a sixteenth embodiment will be described. The sixteenth embodiment relates to a lighting apparatus. FIG. 21 is a diagram illustrating a configuration of the lighting apparatus according to the sixteenth embodiment.

The lighting apparatus 900 according to the sixteenth embodiment can be used for implementing a variety of lighting, such as interior lighting of a building, nighttime lighting of a movable body, and the like. The lighting apparatus 900 includes a vertical cavity surface emitting laser module 901, a fluorescent plate 902, a light receiving device 903, a reflective plate 904, and a lens 905. The vertical cavity surface emitting laser module 901 includes a vertical cavity surface emitting laser according to any of the fifth through twelfth embodiments. The vertical cavity surface emitting laser module 901 may include a vertical cavity surface emitting laser array including a plurality of surface emitting lasers each according to any of the fifth through twelfth embodiments. The fluorescent plate 902 is on a light outgoing side of the vertical cavity surface emitting laser module 901 to diffuse light emitted from the vertical cavity surface emitting laser module 901. The reflective plate 904 reflects light diffused by the fluorescent plate 902. The lens 905 shapes light reflected by the reflective plate 904.

A portion of the light reflected by the reflective plate 904 may be incident on the light receiving device 903. The light receiving device 903 detects the incident light. A control unit (not depicted) may control the lighting apparatus 900 based on the detection result of the light receiving device 903.

A portion of the reflective plate 904 receiving direct light from the vertical cavity surface emitting laser module 901 may have an opening 906 for safety in the event of failure of the fluorescent plate 902. The opening 906 prevents coherent light coming from the vertical cavity surface emitting laser module 901 from being directly emitted outside.

The vertical cavity surface emitting laser module 901 including the vertical cavity surface emitting laser according to any one of the fifth through twelfth embodiments or the vertical cavity surface emitting laser array including the plurality of surface emitting lasers each according to any one of the fifth through twelfth embodiments can be used to obtain the lighting apparatus 900 that is more energy-efficient.

Although the reflecting mirrors, vertical cavity surface emitting lasers, vertical cavity surface emitting laser arrays, projectors, head up displays, movable bodies, head mount displays, optometry apparatuses, and lighting apparatuses have been described with reference to the embodiments, the present invention is not limited to the embodiments, and various modifications or improvements can be made without departing from the scope of the claimed invention.

The present application is based on and claims priority to Japanese patent application No. 2020-029504, filed on Feb. 25, 2020, and Japanese patent application No. 2021-008612, filed on Jan. 22, 2021. The entire contents of Japanese patent application No. 2020-029504 and Japanese patent application No. 2021-008612 are hereby incorporated herein by reference.

### REFERENCE SIGNS LIST

10, 20, 30, 40 Reflecting mirrors
11, 21, 71, 81 First multilayered films
12, 22, 72, 82 Second multilayered films
13 Third multilayered film
111, 121, 131, 221, 711, 711, 721, 721B, 811, 821 Low refractive index layers
111a, 121a, 131a AlGaInN layers
111b, 121b, 131b GaN layers
112, 122, 132, 222, 712, 722, 722A, 722B, 812, 822 High refractive index layers
200, 300, 791, 792, 793, 794, 796, 800 Vertical cavity surface emitting lasers
204, 704, 804 First reflecting mirrors
205, 705, 805 First spacer layers
206, 706, 806 Active layers
207, 707, 807 Second spacer layers
208, 708, 808 Second reflecting mirrors
400 Automobile
500 Head up display (HUD)
501B, 501G, 501R Laser light sources
600 Head mount display (HMD)
900 Lighting apparatus

### CITATION LIST

### Patent Literature

[PTL1] Japanese Unexamined Patent Application Publication No. 2019-153779

### Non Patent Literature

[NPL1] Applied Science 2019, 9, 416

1-40. (canceled)

41. A vertical cavity surface emitting laser comprising:
an active layer;
a first reflecting mirror and a second reflecting mirror, the active layer being between the first reflecting mirror and the second reflecting mirror; and
a first semiconductor layer having electrical conductivity, the first semiconductor layer being between the active layer and the first reflecting mirror,
wherein
the first reflecting mirror includes a first multilayered film and a second multilayered film, the second multilayered film having electrical conductivity and being between the first multilayered film and the first semiconductor layer,
wherein
the first multilayered film includes a first low refractive index layer having a first average refractive index, and a first high refractive index layer having a second average refractive index higher than the first average refractive index; and
the second multilayered film includes a second low refractive index layer having a third average refractive index, and a second high refractive index layer having a fourth average refractive index higher than the third average refractive index,
wherein
assuming that a center wavelength of a reflection band of the first multilayered film is λ,
a sum of an optical film thickness of the first low refractive index layer and an optical film thickness of the first high refractive index layer is λ/2; and
a sum of an optical film thickness of the second low refractive index layer and an optical film thickness of the second high refractive index layer is greater than or equal to (n+1)λ/2 (n is an integer greater than or equal to 1),
wherein
the vertical cavity surface emitting laser further includes an electrode electrically connected with the first semiconductor layer or the second multilayered film.

42. The vertical cavity surface emitting laser according to claim 41,
wherein
a laminate at least including the active layer and the first semiconductor layer has a mesa structure where a portion of the first semiconductor layer serves as a bottom of the mesa structure, and
the electrode is electrically connected with the first semiconductor layer.

43. The vertical cavity surface emitting laser according to claim 41,
wherein
a laminate at least including the active layer, the first semiconductor layer, and the second multilayered film has a mesa structure where a portion of the second multilayered film serves as a bottom of the mesa structure, and
the electrode is electrically connected with the second multilayered film.

44. The vertical cavity surface emitting laser according to claim 41,
wherein
the first reflecting mirror is on a conductive substrate,
a laminate at least including the active layer and the first semiconductor layer has a mesa structure,
at least the first reflecting mirror has an opening, and
the vertical cavity surface emitting laser further comprises a conductor in the opening, the conductor electrically connecting the substrate with the second multilayered film.

45. The vertical cavity surface emitting laser according to claim 41,
wherein
the second multilayered film and the first semiconductor layer are in contact with each other.

46. The vertical cavity surface emitting laser according to claim 41,
wherein
a band-gap difference between the second high refractive index layer and the second low refractive index layer is smaller than a bandgap difference between the first high refractive index layer and the first low refractive index layer.

47. The vertical cavity surface emitting laser according to claim 41,
wherein
the first multilayered film is in an undoped state.

48. The vertical cavity surface emitting laser according to claim 41,
wherein
the second multilayered film has p-type conductivity.

49. The vertical cavity surface emitting laser according to claim 41,
wherein
the first low refractive index layer and the first high refractive index layer are made of nitride semiconductors, respectively,
the first low refractive index layer includes one or more layers respectively having refractive indexes, each of the refractive indexes being lower than a refractive index of GaN, and
the first high refractive index layer includes one or more layers respectively having refractive indexes, each of the refractive indexes being higher than the refractive index of GaN.

50. The vertical cavity surface emitting laser according to claim 41,
wherein
the optical film thickness of the second high refractive index layer is greater than or equal to λ/2.

51. The vertical cavity surface emitting laser according to claim 50,
wherein
at least one of the second low refractive index layer or the second high refractive index layer includes a GaN layer.

52. The vertical cavity surface emitting laser according to claim 41,
wherein
the first low refractive index layer has a laminate structure wherein
an AlₓGa_{y}In_{1-x-y}N layer (x is greater than or equal to 0.9, y is greater than or equal to 0 and smaller than or equal to 0.1) and a GaN layer are alternately laminated, and
the first high refractive index layer includes an InGaN layer.

53. The vertical cavity surface emitting laser according to claim 41,
wherein
the optical film thickness of the second low refractive index layer is smaller than or equal to λ/4.

54. The vertical cavity surface emitting laser according to claim 53,
wherein
a film thickness of the first semiconductor layer is smaller than or equal to 400 nm.

55. A projector comprising:
the vertical cavity surface emitting laser according to claim 41; and
a light deflector configured to deflect light emitted by the vertical cavity surface emitting laser or light emitted by the plurality of vertical cavity surface emitting lasers, wherein
the projector is configured to deflect the light and project an image.

56. A head up display comprising
the vertical cavity surface emitting laser according to claim 41.

57. A movable body comprising
the head up display according to claim 56.

58. A head mount display comprising
the vertical cavity surface emitting laser according to claim 41.

59. An optometry apparatus comprising;
the vertical cavity surface emitting laser according to claim 42.

60. A lighting apparatus comprising
the vertical cavity surface emitting laser according to claim 41.
